(19) United States
(12) Patent Application Publication
(10) Pub. No.: US 2025/0307487 A1
(43) Pub. Date: Oct. 2, 2025

(54) AI-POWERED APPARATUS FOR CODE COMPLIANCE ANNOTATION AND REAL-TIME COLLABORATION IN DESIGN PLANS

(71) Applicant: CodeComply.Ai, Corp., Miami, FL (US)

(72) Inventors: Patrick E Murphy, Miami, FL (US); Johnny Maghzal, Miami, FL (US); Dawn Keller, State College, PA (US); Patrick Hughes, Miami, FL (US)

(73) Assignee: CodeComply.Ai, Corp., Miami, FL (US)

(21) Appl. No.: 19/094,719

(22) Filed: Mar. 28, 2025

Related U.S. Application Data
(60) Provisional application No. 63/572,635, filed on Apr. 1, 2024.

(51) Int. Cl. G06F 30/13; G06Q 30/018

(52) U.S. Cl. CPC G06F 30/13; G06Q 30/018

(57) ABSTRACT

AI-powered apparatus for code compliance related annotation of design plans. A controller and processor receive and analyze a two-dimensional representation of a building design plan. An AI engine identifies design elements such as architectural aspects, walls, and boundaries, represented as pixel patterns. A user interface displays these elements, allowing users to select and annotate them. The system determines positional coordinates for selected elements, updating annotations in real-time to ensure synchronicity across the collaborative environment. The AI engine provides automated annotation suggestions and prioritizes actions based on annotation severity. It compares annotations against a database of safety codes to identify non-compliance issues, alerting users and suggesting adjustments. The apparatus supports real-time collaboration, 3D visualization, and integration with third-party platforms for code compliance services, enhancing workflow efficiency and ensuring adherence to regulatory standards.

### CROSS REFERENCE TO RELATED APPLICATIONS

This application claims priority to U.S. Provisional Application No. 63/572,635, filed Apr. 1, 2024, and entitled AI-POWERED COLLABORATIVE PLATFORM FOR CODE COMPLIANCE ANNOTATION OF INTERACTIVE DESIGN PLANS, the entire disclosure of which is incorporated herein by reference.

### FIELD OF THE INVENTION

The present invention provides systems, methods, and apparatus leveraging artificial intelligence to facilitate enhanced code compliance related annotation of two-dimensional static design plans. More specifically, the present invention introduces a sophisticated platform that enables users to collaboratively annotate, modify, and interact with design elements represented as polygons, lines, and objects as they relate to compliance with fire and safety codes, or other codes mandated by an authority having jurisdiction. Utilizing an AI engine, the system dynamically tracks one or both of annotations and modification of polygons or lines over a time sequence. AI may also ascertain and report out compliance of a design plan with designated annotations as well as ensuring that modifications within a physical building environment are accurately described in the design plans.

### BACKGROUND OF THE INVENTION

The inception of computer-aided design (CAD) software revolutionized the fields of architecture, engineering, and construction. These tools allowed for the precise creation, modification, and optimization of designs in a digital format, significantly reducing the time and effort required for manual drafting. Over the years, CAD software has evolved to offer more sophisticated features, such as three-dimensional modeling and simulation.

Project planning and execution in architecture, engineering, and construction involve multiple stakeholders, including architects, engineers, designers, contractors, and clients. Effective communication and collaboration among these stakeholders are crucial for the successful completion of a project.

Code compliance related annotations in design plans involve marking specific areas, lines, or objects to convey information, instructions, or feedback. These annotations are vital for accurate project execution but can become complex and cumbersome to manage, especially when design plans undergo frequent changes. Traditional methods of annotation often lack the flexibility and intelligence to adapt to changes in the design, leading to confusion, errors, and delays. The practice of annotating design plans has a rich history, deeply embedded in the fields of architecture, engineering, and construction.

Historically, these annotations were made manually on physical drawings, serving as crucial communication tools among architects, engineers, and builders. These handwritten notes, symbols, and drawings provided detailed instructions, specifications, and corrections for design plans. As technology evolved, the transition from physical to digital design plans brought about significant changes in how these annotations were made, shared, and stored.

With the advent of computer-aided design (CAD) software, the process of annotating design plans underwent a transformative shift from analog to digital. This transition allowed for easier modifications, better storage, and sharing options, enhancing overall efficiency. However, such advancements were limited to those with access to the CAD files, and such access is often severely limited. Therefore, despite these advancements, digital annotations often remained static, isolated elements within design files, lacking dynamic integration with the evolving aspects of design plans. Static reference documents, such as those in portable document format (sometimes referred to as “PDF”) include very limited shared editing and annotation capability. This limitation highlighted the need for a more sophisticated approach to managing annotations in a manner that reflects the iterative nature of design and planning processes.

As design projects became more complex and collaborative, the management of annotations grew increasingly challenging. In a traditional setting, changes to a design plan necessitated manual updates to the corresponding annotations, a process fraught with inefficiencies and prone to human error. This issue was compounded when multiple stakeholders were involved, each contributing their annotations, leading to potential conflicts, miscommunications, and discrepancies in the design plan.

Further, collaboration among stakeholders in design projects has always been critical. While several platforms offer collaborative features and some level of annotation capabilities, they often do not fully address the needs of code compliance related annotation in two-dimensional design plans. Most existing solutions do not dynamically link annotations with the underlying design elements, nor do they leverage AI to enhance the annotation process. As a result, users must manually adjust annotations with every change in the design plan, a process that is both time-consuming and prone to errors. This inefficiency underscored the pressing need for a platform that could support real-time, collaborative annotations, dynamically linked to the evolving design plans.

### SUMMARY OF THE DISCLOSURE

Accordingly, the present invention provides an innovative platform that combines the power of AI with advanced collaborative features. Such a platform would not only allow generation user dynamic interfaces based upon a static design plan, such as a PDF file, but also spatially annotate the dynamic user interface. In some embodiments, annotations are intelligently linked to one or more underlying design elements. Annotations may be generated by one or both of a: user, a bot, and an AI Engine. By intelligently linking to one or more underlying design elements, changes to the user interface may automatically reflect in annotations, thereby maintaining relevance and accuracy of the annotations during various uses of the user interface.

The integration of artificial intelligence (AI) to generate dynamic user interfaces based upon static design plan documents presented new opportunities to overcome the limitations of traditional annotation methods. AI technologies are used to automate updating of annotations in response to changes in the dynamic interface based upon a static design plan, predict the impact of such changes (and/or annotations), and facilitate more effective communication among stakeholders over a time sequence. The present invention facilitates a shift towards more intelligent, responsive, and collaborative design tools allowing spatially relevant annotation provided by one or both of a user and an AI Engine (or other automation).

The proposed invention aims to significantly improve communication and efficiency among architects, engineers, and stakeholders by providing a shared space where users can collaboratively annotate, discuss, and modify design plans in real time. This environment fosters a more inclusive and dynamic design process, where feedback and changes are instantly shared and addressed (through AI-assisted analysis), reducing the need for multiple meetings or extensive email chains.

The present disclosure provides methods, apparatus and systems for users (e.g.: architects, owners, developers, engineers, compliance reviewers, builders, and other interested parties or automated bots) to annotate a dynamic interface based upon a static two-dimensional (sometimes referred to herein as “2D”) or three dimensional (sometimes referred to herein as “3D”) references, such as floorplans, design plans, blueprints, and the like, with the aid of artificial intelligence (sometimes referred to herein as “AI” and an AI platform programmed to accomplish the methods described herein as an “AI Engine”).

According to the present invention, automated systems, apparatus, and methods provide tools that empower users to select spatial designations, such as those associated with specific segments, elements or components within a design plan and associate one or more annotations with the spatial designation and/or segment, element, or component.

In some embodiments, automated processes discern a specific type of element present within a design plan based on a pixel-level examination by the AI engine. Elements may encompass a diverse array of features, including but not limited to: walls, windows, doors, stairwells, staircases, ramps, ceilings, floors, columns, beams, roofs, skylights, facades, and an assortment of other architectural components. Furthermore, the present invention provides users with the capability to intelligently annotate these elements (including annotating lines and polygons), significantly enhancing the precision and utility of design plan modifications. This dynamic annotation process, (which may be powered by the AI engine) allows for annotations to adapt in real time to changes within the design plans.

In some embodiments, annotations may be designated to remain accurately aligned with an intended design element, even as modifications are made to the design element and/or other aspects of the design plan. The AI engine may facilitate spatial alignment of an annotation by automatically updating annotations based on the AI Engine's analysis of design components' spatial relationships and dimensions. This level of intelligence in annotation not only streamlines the design review and modification process but also enhances collaborative efforts by maintaining a consistent and up-to-date representation of the design intent across all user interactions.

By enabling detailed and dynamic annotations in a user interface based upon a static design plan, the present disclosure empowers stakeholders involved in a process referencing the design plan to achieve a higher degree of accuracy, efficiency, and collaboration, ultimately leading to the realization of more sophisticated and well-coordinated projects.

Artificial Intelligence (AI) has permeated various sectors, automating, and enhancing tasks that require data analysis, pattern recognition, and decision-making. In the context of design and planning, AI can dramatically transform how annotations, modifications, and interactions with design plans are handled. An AI-powered platform can intelligently interpret and process code compliance related annotations, automate repetitive tasks, and provide predictive insights, thereby enhancing the design process's efficiency and accuracy.

In some embodiments, automated systems described by the present invention may maintain a dynamic user interface similar to an up-to-date digital twin of a portion of a building. The dynamic user interface may reflect thought processes, alterations in a physical environment, or suggestions for improvements, back to the dynamic user interface based upon the static design plan. Such synchronization may facilitate (by way of non-limiting example) more accurate compliance with fire and safety codes mandated by an authority having jurisdiction.

In general, the present invention provides for apparatus and methods related to receiving as input two-dimensional representations (either physical or electronic) and generating one or more pixel patterns based upon automated processing of the two-dimensional representations. The pixel patterns are analyzed using computerized processing techniques to mimic the perception, learning, problem-solving, and decision-making formerly performed by human workers (sometimes referred to herein as artificial intelligence or “AI”). The AI analysis process is repeated for multiple two-dimensional representations over time, each two-dimensional representation including a change to the design of a building. The AI processes denote, and track changes made in the sequence of two-dimensional representations of design documents.

Based upon AI analysis of pixel patterns derived from the two-dimensional references and knowledge accumulated from increasing volumes of analyzed two-dimensional references, interactive user interfaces may be generated that allow for a user to modify dynamic two-dimensional representations of features gleaned from the two-dimensional reference. The interactive user interfaces may enable users to select specific portions or segments on the design plans, wherein the AI engine employs AI processing to determine the elements or components present within the chosen segment by analyzing the pixel patterns of the two-dimensional references. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from previous work, whether or not a human was involved, hence the importance of integrating our AI with existing databases.

In still another aspect, in some embodiments, enhanced interactive interfaces may include one or more of: user definable and/or editable lines; user definable and/or editable vectors; and user-definable and/or editable polygons. The interactive interface may also be referenced to generate diagrams based on the lines, vectors and polygons defined in the interactive interface. Still further, various embodiments include values for variables that are definable via the interactive interface with AI processing and human input.

According to the present invention, analysis of pixel patterns and enhanced vector diagrams and/or polygon-based diagrams may include one or more of: neural network analysis, opposing (or adversarial) neural networks analysis, machine learning, deep learning, artificial intelligence techniques (including strong AI and weak AI), forward propagation, reverse propagation and other method steps that mimic capabilities normally associated with the human mind, including learning from examples and experience, recognizing patterns and/or objects, understanding and responding to patterns in positions relative to other patterns, making decisions, solving problems. The analysis also combines these and other capabilities to perform functions the skilled labor force traditionally performed.

The methods and apparatus of the present invention are presented herein generally, by way of example, to actions, processes, and deliverables important to industries such as the construction industry, by providing users with the capability to intelligently annotate design plan elements (including annotating lines and polygons). Building upon its innovative capabilities, the present invention further enhances the design and planning process by offering automated suggestions for annotating design plan elements. Leveraging the power of artificial intelligence, the system intelligently generates recommendations for annotations, streamlining the initial stages of the annotation process. This proactive feature is designed to facilitate the rapid identification and marking of key design elements, ensuring comprehensive and meaningful annotations from the outset.

Moreover, the invention dynamically updates annotations in response to modifications within the design plan. This responsiveness is not merely reactive; it may be anticipatory, guided by the AI engine's analysis of existing annotation threads and historical data pertaining to similar design elements or modifications. Through this advanced analysis, the platform identifies patterns and commonalities in how certain design changes have been annotated in the past, applying this insight to suggest or automatically adjust annotations in the current context. By integrating past learnings and contextual understanding, the system ensures that annotations are consistently aligned with best practices and the specific nuances of the project at hand. Consequently, this invention not only adapts to the evolving needs of the design plan but also evolves itself, learning from each interaction to provide more informed, precise, and helpful annotations (or annotation suggestions) over time.

In some specific examples, the present invention uses machine learning and/or artificial intelligence to identify architectural aspects, such as: walls, stairwells, floors, ceilings, doors, windows, in order to assess compliance with fire and safety codes mandated by an authority having jurisdiction. The present invention identifies such architectural aspects, and other building features, and provides dynamic association between design plan elements such as objects, polygons, or lines and their corresponding annotations. Such embodiment ensures that when a user moves a design plan element within the digital workspace as part of design plan modification, associated annotations are automatically moved in tandem with the element. This feature may be powered by an underlying artificial intelligence (AI) engine, which intelligently recognizes the linkage between the spatial characteristics of design elements and their annotated descriptions or markers, or by a controller executing logic, such as Boolean logic.

Upon initiating a move action for a given design element, the system calculates the new position of the element and simultaneously updates the positions of all related annotations. This process is seamless and requires no additional input from the user, thereby enhancing the efficiency of the design modification process. The system ensures that annotations retain their spatial relevance to the design elements they describe, regardless of how these elements are repositioned within the design plan. By automating the concurrent movement of annotations with their respective design elements, the invention significantly reduces the risk of errors and streamlines the workflow. Furthermore, the intelligent handling of this feature extends to the recognition of complex movements and transformations of design elements, such as rotations, scaling, or mirroring. The AI engine adeptly adjusts the annotations to maintain their correct orientation and relationship to the elements, providing a robust solution that supports a wide range of design activities.

Further, the system is equipped to generate automated annotations in response to changes within the design plan or specific design plan elements, thereby offering a proactive approach to documenting and communicating these modifications. This functionality may be particularly valuable for tracking alterations over the course of a project's development, ensuring that all stakeholders are promptly informed of updates. Additionally, in instances where changes occur to elements that previously lacked annotations, the system leverages its AI engine to intelligently create appropriate annotations for these newly modified elements. These automated annotations are generated based on a sophisticated analysis conducted by the AI engine, which considers the nature of the change, the context within the overall design plan, and historical data on similar modifications. This capability ensures that every change, regardless of its prior annotation status, is accurately documented and communicated, enhancing the collaborative and iterative nature of the design process.

In some preferred embodiments, the AI Engine is seamlessly integrated with databases housing a repository of past similar projects. These databases serve as helpful resources, facilitating the AI engine's learning process by drawing insights from diverse user decisions made in comparable prior works. This integration empowers the AI Engine with a wealth of accumulated knowledge, enhancing its ability to offer informed and contextually relevant recommendations.

A static reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include, for example, rooms, residential units, hallways, stairs, dead ends, windows, or other discrete aspects of a building.

A scaling process is applied to the floorplan and size descriptors are assigned to the discernable components. In addition, distances, such as, for example, a distance to an exit from the furthest point in a residential unit are calculated.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (such computerized processing techniques are sometimes referred to herein as artificial intelligence or “AI” processing or analysis).

Based upon AI analysis of pixel patterns derived from the two-dimensional references and knowledge accumulated from increasing volumes of analyzed two-dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional references.

In specific embodiments of the invention, the method involves several key processes: receiving two-dimensional representations of a design plan as input into a controller housing the AI engine; generating pixel patterns through automated processing of these representations; analyzing multiple two-dimensional representations over time using the AI engine; representing the design plan (or a portion of it) as a raster image; utilizing the AI engine on the controller to analyze the raster image, identifying components depicted in the design plan; determining the scale of these components; constructing a user interface featuring various components, arranging them to establish boundaries; generating features' areas or lengths based on these boundaries; enabling user selection of a segment within the design plan via the user interface; leveraging the AI engine to identify the component(s) within the chosen segment, employing AI analysis of the segment's polygons; and finally, displaying comprehensive data related to the identified component(s) on the user interface. Furthermore, alternative embodiments may comprise computer systems, apparatus, and computer programs stored on one or more computer storage devices. Various configurations may be tailored to execute the aforementioned methods and functionalities.

In specific embodiments of the invention, the process of selecting a segment may involve one or both of the following actions: marking around or on the desired segment or design element directly within the user interface or utilizing a polygon shape tool accessible on the interface, enabling users to drag and position the shape onto the desired segment. Moreover, the selection of a segment can be initiated either manually by a user or automatically by the AI engine. Additionally, when employing the polygon shape tool, users may choose from a range of polygon shapes provided by the AI engine within the user interface for selection and placement.

In specific embodiments of the invention, the AI engine analyzes the selected segment or design element based on pixel-level analysis of the selected segment or design element area within the design plan covered by the user-provided marking or the selected polygon shape. The pixel-level analysis may comprise considering the pixels of the two-dimensional representation for analysis if the pixels are at and/or around a tolerable distance from the marking or boundaries of the polygon shape. The pixel-level analysis may comprise analyzing the polygon pixel patterns of the segment covered by the selected polygon shape. The pixel-level analysis may further comprise considering the pixels of the two-dimensional representation for analysis if the pixels are at a predefined distance from each other creating a particular spatial relationship. The spatial relationship may be defined by a user or automatically learned by the AI engine.

In some embodiments of the present invention, the system may include management and interaction of annotations within the design plan to ensure the integrity and utility of collaborative feedback. In such a system, annotations made by any user cannot be directly deleted or significantly altered by others without the original annotator's consent. Should any user attempt to modify or delete an annotation, the system, powered by the artificial intelligence (AI) Engine, automatically triggers a notification process. This notification is sent to the original user who added the annotation, providing them with the option to approve or disapprove the proposed change or deletion. This mechanism ensures that each annotation's original intent and value are preserved until the contributor validates the necessity for alteration, thereby maintaining a coherent and collaborative annotation history.

Further enhancing user interaction with annotations, such embodiments may also incorporate features such as the ability for users to ‘like’ annotations made by others. These interactions serve a dual purpose: firstly, as a means of acknowledging the usefulness or relevance of specific annotations within the collaborative environment, and secondly, as a valuable dataset for the AI Engine. The AI Engine utilizes these interactions to learn about the relevance and utility of annotations in relation to the associated design elements. By analyzing patterns in which annotations receive positive engagement, the AI Engine can refine its understanding of what constitutes valuable and pertinent annotations within various contexts of the design plan.

Moreover, such embodiments may leverage additional innovative methods for the AI Engine to learn from annotations. For instance, the system may analyze the frequency and context of annotations that consistently lead to design modifications, thereby identifying trends in critical feedback that directly influence design outcomes. Another method involves the AI Engine examining the correlation between the spatial positioning of annotations and changes in design elements, enabling the system to predict areas within a design plan that may require more detailed scrutiny or are prone to revisions.

These unique learning mechanisms empower the AI Engine to not only facilitate a more dynamic and interactive annotation environment but also continuously improve the platform's capability to support effective design collaboration. By integrating these features, the invention fosters a rich, interactive, and intelligent design process, where annotations become a central component of learning, decision-making, and innovation in the collaborative development of design plans.

In some embodiments of the present invention, the system accommodates a variety of annotation formats, providing a versatile and robust platform for user interaction with design plans. Users can annotate design elements using text, comments, images, videos, or voice recordings captured via a microphone. This multimodal annotation capability enables users to convey their feedback or instructions in the most appropriate format for the context, enhancing the clarity and effectiveness of communication within the design process.

The AI Engine, integral to the system, utilizes its advanced algorithms to not only process and recognize these diverse forms of annotations but also to suggest improvements. For instance, the AI Engine might propose more concise text annotations, recommend additional visual annotations for clarity, or suggest the inclusion of a video or voice annotation to provide a more comprehensive explanation of complex design aspects. The AI Engine is designed to learn from user interactions and preferences, continuously adapting its suggestions to optimize the effectiveness of annotations. Furthermore, some embodiments may allow the AI Engine to convert annotations from one format to another where beneficial. For example, a text annotation could be converted into a voice annotation for users who may prefer auditory instructions, or an image annotation could be converted to a video to provide a dynamic view of a design element. The AI Engine is also capable of semantic understanding, where it can contextualize voice annotations and convert spoken words into text annotations, complete with relevant tags and markers on the design plan.

By providing such a diverse range of annotation formats and the intelligent processing of these annotations, the present invention fosters a highly adaptable and user-friendly environment. It ensures that all contributors can engage with the design plan in the manner that best suits their needs and expertise, while also allowing the AI Engine to learn from and adapt to the varied annotation styles, further enhancing the collaborative design process.

In one embodiment of the present invention, the system employs an AI engine that performs intelligent adjustments to annotations within a two-dimensional (or three-dimensional) design plan. As changes occur within the design, such as the repositioning of walls or the resizing of rooms, the AI engine responds by automatically updating the annotations linked to those elements, thus preserving the annotations' accuracy and relevance.

In specific embodiments of the invention, the method encompasses receiving a two-dimensional representation of at least a portion of a building into a controller and analyzing this representation with an AI engine to identify various components within it, which are then represented as a pattern of pixels in a raster image. This is followed by generating an interactive user interface that includes multiple vertices, utilizing dynamic lines and polygons to depict these identified components as dynamic, interactive elements. The process advances to selecting a design element within this interface for annotation, allowing users to input annotations directly associated with selected design element. Subsequently, the AI engine determines the precise positional coordinates (x, y, z) of the selected design element, ensuring that these coordinates are accurately associated with the corresponding annotations.

Moreover, in-depth pixel-level analysis may involve considering spatial relationships between pixels within the two-dimensional representation, ensuring a predefined distance between them, thus refining the precision of the analysis process.

In some embodiments, the two-dimensional reference input may be file extensions that include but are not limited to: DWG, DXF, PDF, TIFF, PNG, JPEG, GIF, or other types of files based upon a set of engineering drawings. Some two-dimensional reference references may already be in a pixel format, such as, by way of a non-limiting example, a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. As some architects, design firms and others who generate engineering designs for buildings may be reluctant to share raw CAD files with others, the present invention provides a solution that does not require raw CAD files.

In other examples, such as for older structures, a drawing or other 2D or 3D representation may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or In some embodiments, via an application running on a smart device. In some embodiments, a user may operate a scanner or a smart device with a camera to create the file containing the image on the smart device.

In some embodiments, a system utilizes pixel patterns and polygon patterns in sizing analysis of the selected segments or design elements of design plans. The system incorporates a user-adjustable and/or AI-adjustable feature for sizing variations, utilizing percentage variation in pixel positions relative to other pixel positions within a defined window of the segment selection. It may involve convolutional filters for zero-shot and one-shot approaches, leveraging generative models and template matching. Another embodiment may incorporate relative positioning of pixels, employing mathematical representations, algorithms, and vector-based approaches for analyzing distances, angles, and clustering vectors into symbols. The system aims for optimization based on speed, quality, cost-effectiveness, durability, aesthetics, financial criteria, supply chain, labor costs, subcontractor selection, scope of work, location, equipment, spatial relevance, clearance, covering area, floor, ceiling, paths, plumbing, gas/chemical lines, cables, electrical wiring, and rule-based criteria. Users can select measurements such as length, area, volume, atmospheric volume, and relative height, further refining the system's analysis. This versatile approach prioritizes user-defined preferences and customizable variables to streamline decision-making and planning.

A primary advantage of AI analysis in this scenario is its capacity to analyze complex pixel patterns, vectors, and polygons using knowledge derived from previous experiences. This knowledge is not confined to the work of a single individual but can be harnessed from a select group of experts or shared learnings from similar past projects. This means that the AI system has access to a vast pool of information and insights, enabling it to make informed and effective decisions. Furthermore, the speed at which AI analysis can derive new and improved work based on the current design plan is a remarkable asset. The capabilities of the AI Engine in generating and managing annotations far exceed human processing abilities, positioning it as an invaluable asset for innovating and enhancing design plans. Through its advanced computational power, the AI Engine can swiftly analyze complex design elements, identifying opportunities for optimization and suggesting refinements that might not be immediately apparent to human users. This functionality extends to the automated generation of annotations, where the AI Engine meticulously documents each suggested alteration, providing a detailed rationale and potential impact analysis for the change.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates an exemplary method for annotating a design element on the design plan in the collaborative environment of the present invention.

FIG. 1D illustrates an exemplary interface for providing automated annotation suggestions to users during annotation process.

FIG. 1E illustrates an exemplary settings window with various setting options as per some embodiments of the present invention.

FIG. 1F illustrates an exemplary method for relocating a design element from one position to another on a design plan in some embodiments of the present invention.

FIGS. 2A, 2B, 2C and 2D illustrate a two-dimensional representation of a floor plan and an AI analysis of the same to assess boundaries and design elements.

FIGS. 3A-3D show various views of the AI-analyzed boundaries and design elements overlaid on the original floorplan including a table illustrated to contain hierarchical dominance relationships between area types.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols and an exemplary method for making changes to a design element of the design plan.

FIG. 8 illustrates exemplary processor architecture for use with the present disclosure.

FIG. 9 illustrates exemplary mobile device architecture for use with the present disclosure.

FIGS. 10A-10B illustrate additional method steps that may be executed in some embodiments of the present invention.

FIG. 11 illustrates additional method steps that may be executed in some embodiments of the present invention.

FIG. 12 illustrates a conceptual framework showing multiple layers involved in the AI-powered collaborative system for code compliance related annotations of a design plan in accordance with the present invention.

FIG. 13 illustrates an exemplary AI-powered collaborative system in accordance with the present invention.

FIG. 14 illustrates an exemplary diagram showing various aspects of the present invention.

FIG. 15 illustrates an exemplary two-dimensional representation of a design plan having known positional coordinate markings for determining positional coordinates of a selected design element.

FIG. 16 illustrates an exemplary user interface of an AI-powered collaborative platform designed to optimize code compliance related annotation process in accordance with the present invention.

### DETAILED DESCRIPTION

The present invention provides systems, methods and apparatus for a comprehensive interactive platform that significantly enhances the collaborative design process. Within this platform, users can seamlessly select design elements for annotation within a digital representation of a building. The AI engine, a core component of this system, leverages historical data and current context to suggest automated annotations, optimizing the annotation process by providing users with intelligent, contextually relevant suggestions that align with the project's specifications and goals.

In a further embodiment of the present invention, the platform incorporates social interaction features that enable users to engage with the annotations made by their peers through mechanisms such as commenting, liking, or disliking. This interaction not only encourages a dialogue about the design elements and annotations but also contributes to a feedback system where the AI engine can observe and learn from user interactions. As users comment on or react to annotations, the AI engine analyzes these responses, utilizing them to refine the quality and relevance of future automated annotation suggestions. Moreover, the system may also allow for an approval workflow, wherein annotations can be approved or disapproved by authorized users or automatically by the AI engine depending upon the positive or negative reactions to the annotations. This ensures that the annotations not only become more accurate over time but also adhere to the collective knowledge and preferences of the team, thereby enhancing the collaborative design process.

In a specific embodiment of the present invention, the AI engine leverages sophisticated analysis of annotations within the design plan to intelligently determine the order of installation, service, or actions required for annotated design elements. This determination is based on the detected severity or importance of the annotations associated with each design element. By evaluating factors such as urgency, compliance requirements, project timelines, and resource availability, the AI engine prioritizes tasks in a manner that optimizes workflow efficiency and ensures critical project milestones are met.

For instance, if an annotation on a structural beam indicates a compliance issue with safety standards, the AI engine assigns a higher severity level to this task, prioritizing it over less critical modifications. Similarly, if an electrical installation is annotated as a prerequisite for subsequent tasks within the project, the AI engine schedules this installation early in the action order. This dynamic prioritization ensures that the project progresses logically and efficiently, minimizing delays and optimizing resource allocation.

This embodiment represents a significant advancement in project management technology, as it not only automates the task scheduling process but also adapts in real-time to changes within the design plan and the annotations. By doing so, it supports a more agile and responsive project execution strategy, directly contributing to the success and quality of architectural, engineering, and construction projects.

In some embodiments of the invention, the system focuses on enhancing the annotation process by providing automated suggestions. The AI engine analyzes an extensive annotation database comprising historical textual and multimedia annotations. By recognizing patterns and contexts in which annotations were previously used, the system suggests relevant annotations to users as they interact with specific design elements in the digital design plan. This predictive assistance streamlines the annotation process, promotes consistency across projects, and helps users quickly identify and apply best practices and solutions previously successful in similar scenarios.

In some embodiments of the invention, the focus is on enforcement of fire safety codes, standards, and compliance requirements within the design planning phase, leveraging the sophisticated capabilities of the AI engine. The system examines each annotation and design element presented within the digital design plan, utilizing a comprehensive database that encompasses a wide array of regulatory criteria specific to architecture, engineering, and construction standards. This thorough scanning process enables the AI to identify any discrepancies, potential violations, or areas of non-compliance that may exist within the plan.

Upon detecting issues, the AI engine actively engages users by flagging these concerns directly within the user interface, highlighting the specific elements in question. It may go further by suggesting actionable modifications or alternative solutions that can bring the design into full compliance with the necessary standards. Users receive tailored alerts and guidance, effectively offering a consultative approach to rectify compliance issues. This system's capacity to preemptively address compliance ensures that design plans are vetted for regulatory adherence from the outset, significantly reducing the likelihood of encountering costly modifications during or after the construction phase.

Moreover, this embodiment serves to streamline interactions with regulatory bodies and approval processes. By providing a platform that inherently aligns with regulatory expectations, the system facilitates a smoother, more efficient pathway from project conception through to completion. The preemptive correction of compliance issues accelerates the approval process, minimizing delays and fostering a more productive relationship between project stakeholders and regulatory authorities.

In some other embodiments of the present invention, the AI engine is equipped to simulate “What If” scenarios, providing a dynamic tool for planning and decision-making within the architectural and construction domains. This feature enables users to explore various hypothetical modifications to the design plan, design elements, and annotations and assess their potential impacts without committing to actual changes. By inputting different “What If” conditions, such as altering aspects of a design element, repositioning structural components, or changing the dimensions of space, the AI engine projects the consequent effects on the design's compliance with a relevant fire and/or safety code.

In some embodiments of the present invention, the collaborative platform integrates a comprehensive question-and-answer feature designed to facilitate communication among the various parties involved in a construction project. This feature allows users to pose questions directly within the interface, specifically targeting aspects of the design plan or related to specific annotations. Utilizing natural language processing and a deep understanding of the project's context, the AI engine sifts through (or otherwise processes) database of annotations, design elements, and associated documentation to provide accurate, automated answers.

Additionally, the platform can catalog these interactions, creating a searchable knowledge base that grows increasingly rich over time. As more questions are asked and answered, the AI engine continually refines its ability to understand and respond to inquiries, improving the accuracy and relevance of its automated responses.

In the following sections, detailed descriptions of examples and methods will be given. The description of both preferred and alternative examples, though thorough, are exemplary only. It is understood by those skilled in the art, that various modifications and alterations may be apparent and within the scope of the present invention. Unless otherwise indicated by the language of the claims, the examples do not limit the broadness of the aspects of the underlying invention as defined by the claims.

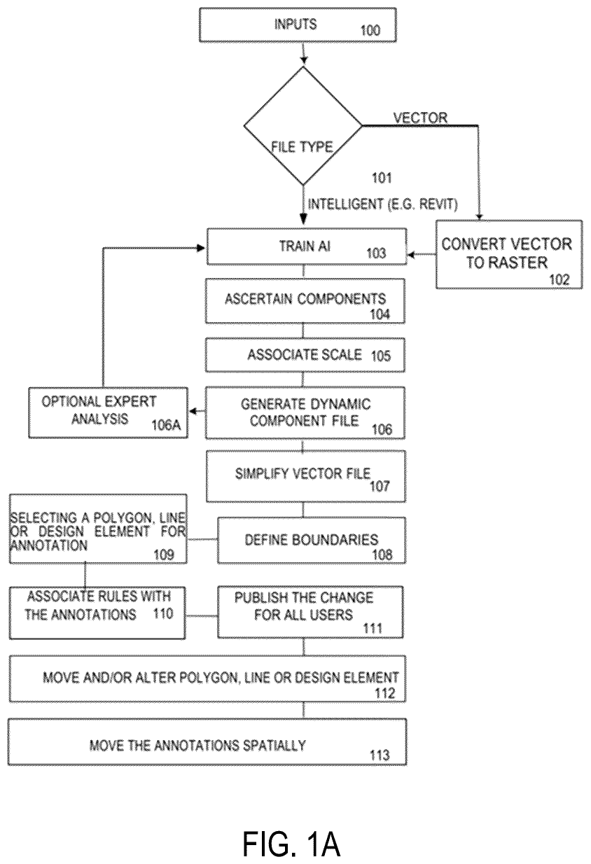

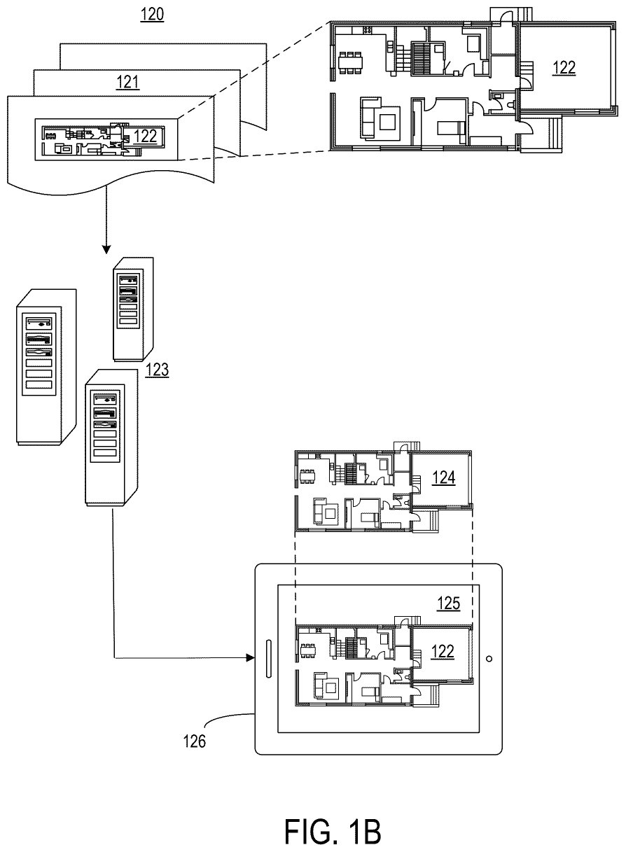

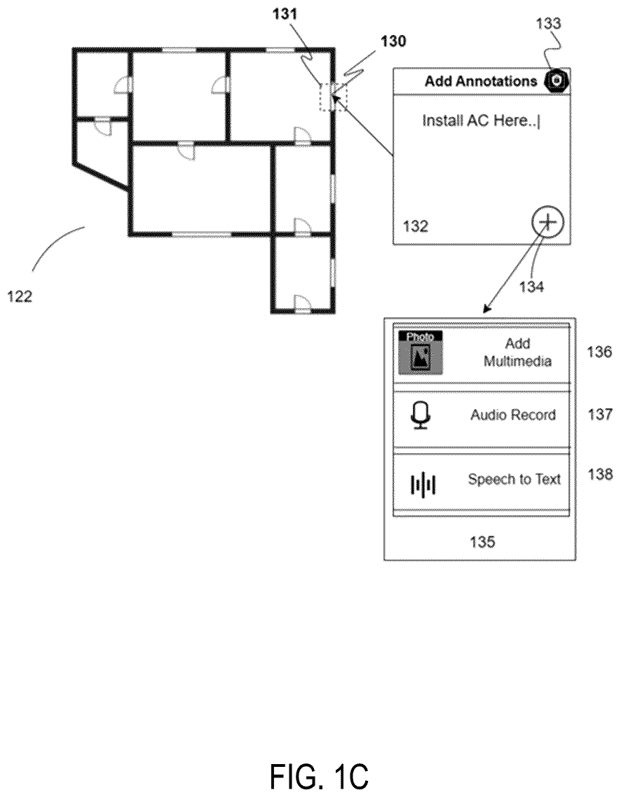

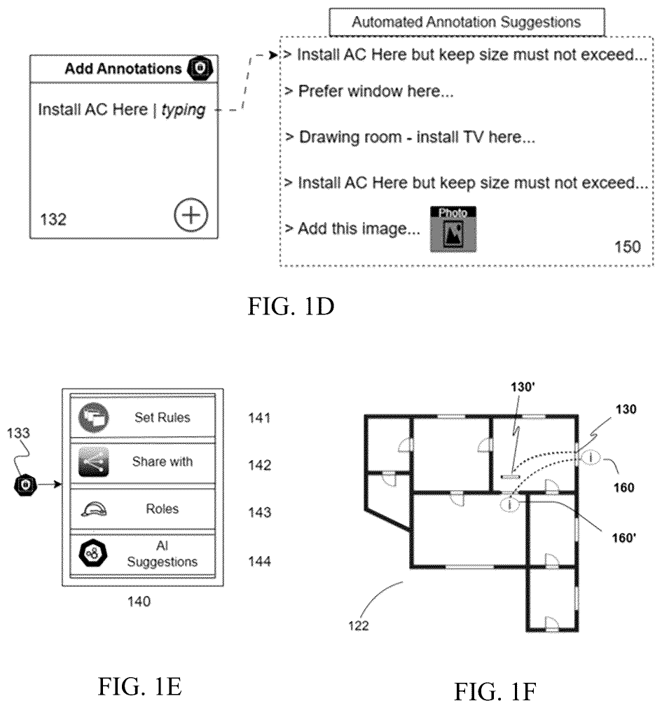

Referring now to FIG. 1A, a general flow diagram showing some preferred embodiments of the present invention as illustrated. At step 100, a design plan (which may be a design plan or dynamic architectural design file e.g., a Revit® compatible file) indicating aspects of a building; is input into a controller or other data processing system using a computing device. The design plan may include an item of a known size, such as, by way of a non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide).

Input of a two-dimensional reference (i.e., design plan) into the controller may occur, for example, via known ways of rendering an image as a vector diagram, such as via a scan of paper-based initial drawings; upload of a vector image file (e.g., encapsulated postscript file (epf file); adobe illustrator file (ai file); or portable document file (pdf file). In other examples, a starting point for estimation may be drawing file in an electronic file containing a model output for an architectural floor plan. In still further examples, other types of images stored in electronic files such as those generated by cameras may be used as inputs for automated processes.

In some embodiments, the design plan may be file extensions that include but are not limited to: DWG, DXF, PDF, TIFF, PNG, JPEG, GIF, or other types of files based upon a set of engineering drawings. Some design plans may already be in a pixel format, such as, by way of a non-limiting example, a two-dimensional reference in a JPEG, GIF, or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged coupled device to create the file containing the image on the smart device.

In some embodiments, a degree of the processing as described herein may be performed on a controller, which may include a cloud server, a standalone computing device or a smart device. In many examples, the input file may be communicated by the smart device to a controller embodied in a remote server. In some embodiments, the remote server, which is preferably a cloud server, may have significant computing resources that may be applied to AI algorithmic calculations analyzing the image.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software-only embodiments of the AI engine may be run on one or more of: local computers, cloud servers, or on smart device processing environments.

At step 101, the controller may determine if the design plan received into the controller includes a vector diagram. If a file type of the received design plan, such as an input architectural floor plan technical drawing, includes at least a portion that is not already in raster graphics image format (for example that it is in vector format), then the input architectural floor plan technical drawing may be transformed to a pixel or raster graphics image format in step 102. Vector-to-image transforming software may be executed by the controller, or via a specialized processor and associated software.

In some embodiments, the controller may determine the pixel count of a resulting rasterized file. The rasterized file will be rendered suitable for the controller hosting an artificial intelligence engine (“AI engine”) to process, the AI engine may function best with a particular image size or range of image size and may include steps to scale input images to a pixel count range in order to achieve a desired result. Pixel counts may also be assigned to a file to establish the scale of a drawing—for example, 100 pixels equals 10 feet. As an illustrative example, images can be resized to dimensions such as 1024×1024, 512×512, or other dimensions that may be appropriate for the AI engine to function in a better way.

In various examples, the controller may be operative to scale up small images with interleaved average values with superimposed Gaussian noise as an example, or the controller may be operative to scale down large images with pixel removal. A desired result may be detectable by one or both the controller and a user. For example, a desired result may be a most efficient analysis, a highest quality analysis, a fastest analysis, a version suitable for transmission over an available bandwidth for processing, or other metric.

At step 103, training (and/or retraining) of the AI engine is performed. Training may include, for example, manual identification of patterns in a rasterized version of an image included in a design plan that correspond with architectural aspects, walls, fixtures, piping, duct work, wiring or other features that may be present in the two-dimensional reference. The training may also include one or more of: identification of relative positions and/or frequencies and sizes of identified patterns in a rasterized version of the image included in the design plan.

In some embodiments, and in a non-limiting sense, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based on the presence of architectural features, such as walls, doorways, windows, stairs, and the like.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. A boundary within the context of a design plan may signify the presence of a wall. Using deep artificial neural networks, original architectural floor plans (along with any labeled boundaries) may be used to train AI models to make predictions about what is inside a boundary. In exemplary embodiments, the AI model may be given over ˜50,000 similar architectural floor plans to improve boundary-prediction capabilities.

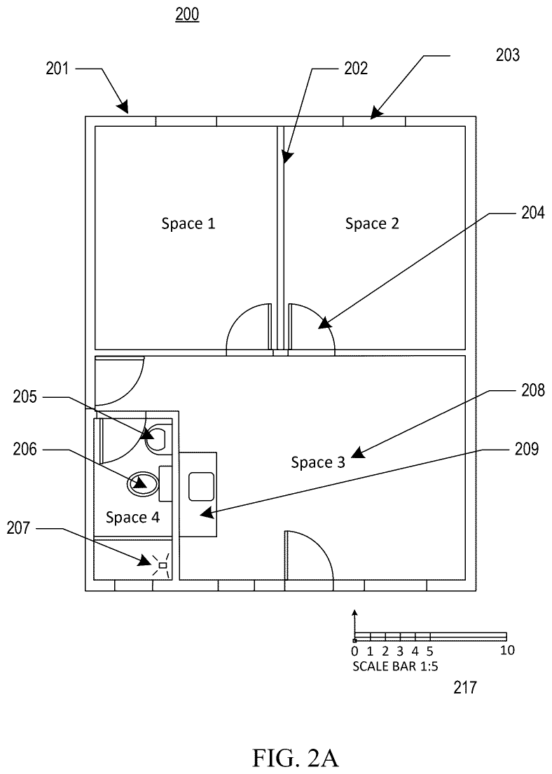

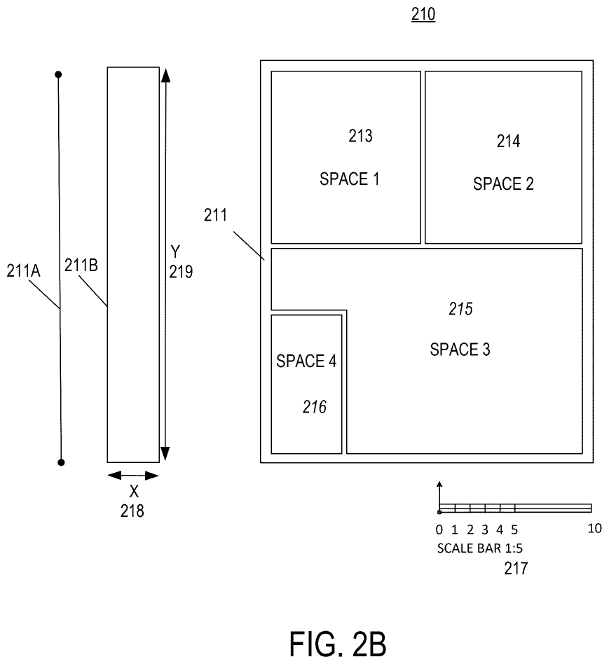

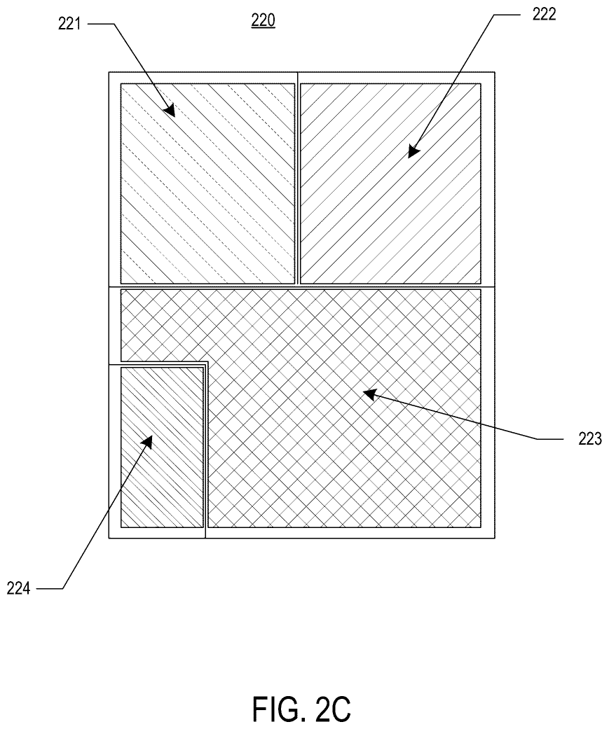

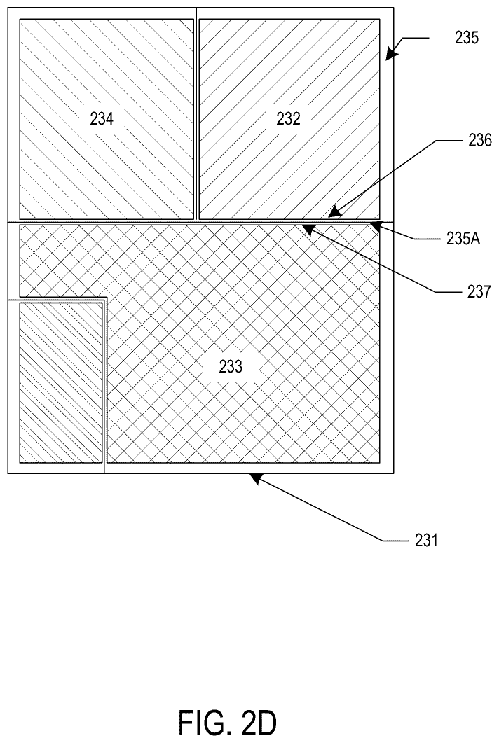

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. (An exemplary AI-processed two-dimensional reference that includes a design plan and/or a floorplan 210, with boundaries 211 predicted, is shown in FIG. 2B, based on the floorplan of FIG. 2A).

In still another aspect, in some embodiments, a controller may access data from various types of BIM and Computer Aided Drafting (CAD) design programs and import dimensional and shape aspects of select spaces or portions of the designs as they are related to a design plan.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects, fixtures, duct work, wiring, piping, or other items included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as a line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shapes.

At step 105, a scale (e.g., FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale or dimension for a particular image, building component, a wall, a boundary, a drawing, or other two-dimensional reference. The drawing scale, may for example, be in inches: feet, centimeters: meters, or any other appropriate scale.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference (or design plan) and proportioned according to that length. The known length of the wall can be determined from the markings or text on the design plan or can be specified by a user as an input. A known length or width of any other building component can be determined or entered by the user. Based on such known length or width of one building component, the scale can be proportioned, and dimensions of other building components can be calculated.

At step 106, a controller is operative to generate an interactive user interface with dynamic components (design elements) that may be manipulated by one or both of user interaction and automated processes. Any or all of the components in a user interface may be converted to a version that allows a user to modify an attribute of the components, such as the length, size, beginning point, end point, thickness, or other attribute. In some embodiments, a boundary may be treated as a component or a wall and manipulated in a similar manner.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 106A, in some embodiments, components presented in the interactive user interface may be analyzed by a user and refinements may be made to one or more components (e.g., size, shape and/or position of the component). In some embodiments, user modifications may also be input back to the AI engine to train the AI engine. User modifications provided back to the AI Engine may be referenced to make subsequent AI processes more accurate, efficient, fast, trained and/or enable additional types of AI processes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or endpoint, associate a pattern of pixels with a predefined shape corresponding with a known component or otherwise modify a shape formed by a pattern of pixels.

In addition, some embodiments that utilize the recognition step transform features such as windows, doorways, vias and the like to other features and may remove them and/or replace them as elements-such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons.

In another aspect, in some embodiments, one or both of a user and a controller may indicate a component type for a boundary. Component types may include, for example, one or more of line segments, polygons, multiple line segments, multiple polygons, and combinations of line segments and polygons.

At step 108, a controller (such as, by way of non-limiting example, a cloud server) operative as an AI engine may create AI-predicted dynamic boundaries that are arranged to form a representation of the submitted design plan that does not include the boundaries that bound it.

In various embodiments, a boundary may be used to define a unit, such as a residential unit, a commercial office unit, a common area unit, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may in turn be used as a basis for modifying an occupant load, defining an egress path, classifying a space, or other purposes.

For example, a change in a boundary may make an area larger. The larger area may be a basis for an increase in occupancy load. The larger area may also result in a longer path from the furthest point in the defined area to a point of egress (e.g., if a user chooses to use a worst case in determining an egress route). Empowering users with flexibility, the present invention allows for seamless modifications to room boundaries, lines, and polygons, enabling the alteration of shapes and sizes to adhere to safety codes with automated revision suggestions to design plans. This dynamic feature not only ensures compliance with regulatory standards but also caters to user preferences or priorities, allowing them to retain the opulence and aesthetic appeal of their spaces. Whether it is aligning with specific safety code requirements or enhancing the overall user experience by accommodating individual tastes, the present invention offers a harmonious blend of functionality and personalization. Users can effortlessly tailor their rooms to meet both regulatory guidelines and their own vision, striking a balance between compliance and the creation of spaces that truly reflect their unique style and preferences.

At step 109, the present invention provides an interface mechanism within the user interface that enables selection and manipulation of specific design elements, such as polygons, lines, or predefined design elements on the floor-plans for annotation purposes. This interface mechanism allows users to select these elements directly within the digital workspace and assign annotations pertinent to the project's needs (or to the selected design element). The selection process is facilitated by the system's AI engine, which offers an intuitive and user-friendly method to identify and delineate various elements within the two-dimensional design plans. Users can choose the desired segment (design element) for annotation by marking around or on it directly, double clicking on the design element, or by utilizing a design element selection tool in various toolbars on the user interface provided by the system.

At step 110, following the selection of a design element for annotation, the present system may also allow users to associate specific rules with these annotations. This association facilitates enforcing constraints, automating responses, and guiding interactions based on the annotated information. For instance, if a user annotates a wall to note the requirement for a fire-resistant material, the system may automatically enforce a rule that aligns this annotation with the relevant safety codes. In some embodiments, users may be presented with automated suggestions (for association) with a list of rules that might be applicable to a type of annotation or design element to be annotated. These rules can also be used to trigger notifications to other users, invoke further actions by the AI engine, or to cause the design plan to adapt to these stipulations accordingly. This feature may serve to maintain a logical and coherent structure within the annotated design plan, ensuring that all subsequent interactions with the annotated elements are consistent with the defined rules and project standards.

At step 111, the system may be designed to publish the added annotations, rules and any other changes made by users within the interactive user interface. These changes may further include modifications to annotations, boundaries, and design elements. Once published, the modifications are synchronized across all users' interfaces, providing real-time updates to all stakeholders. This ensures that every team member, regardless of their geographical location, has access to the most current version of the design plan.

At step 112, users can manipulate design elements directly within the interactive user interface. The AI engine supports this process by providing tools that enable users to select and modify elements such as polygons representing rooms or areas, lines denoting boundaries, or other design features. These modifications may intelligently be analyzed by the AI engine, which then adjusts all related annotations and data to reflect these changes. As a design element is moved or reshaped, the AI engine ensures that the spatial integrity and relevance of annotations are maintained, offering an immediate visual feedback loop. This functionality is useful for iterative design processes where design elements frequently need to be adjusted to explore different design scenarios or to respond to changing project constraints.

At step 113, in response to the movements and alterations of design elements, the corresponding annotations may be repositioned to maintain their spatial and informational integrity. The AI engine automatically handles the relocation of annotations in real time as design elements are moved or transformed within the user interface. Whether a design element is moved, rotated, scaled, deleted, or undergoes more complex transformations, the associated annotations adjust their positions accordingly. This automated feature may save time and reduce the risk of human error, ensuring that the annotations' context and clarity are preserved throughout the design iteration process. The AI engine's ability to perform this task demonstrates its advanced understanding of spatial relationships and its role in facilitating a dynamic and interactive design environment.

In some embodiments of the present invention, the AI engine is responsible for managing and enforcing associated rules pertaining to the movement or alteration of design elements that have associated annotations. The system is configured to recognize user roles and privileges, ensuring that only those users with the appropriate permissions can make changes, move, or alter design elements or their associated annotations. If a user without the necessary rights attempts such actions, the AI engine intervenes, restricting these unauthorized modifications. This enforcement of rules maintains the integrity of the design plan and ensures compliance with collaborative protocols. It also protects the annotations' continuity and relevance, as any changes to design elements are reflected in real-time, preserving the accuracy and context of the collaborative effort.

In some embodiments of the present invention, the AI engine may include a learning mechanism that constantly evaluates past annotations in relation to similar design elements. This historical analysis allows the AI engine to identify patterns and preferences in the annotation behaviors of users. Consequently, when a specific design element is selected for annotation, the AI engine may proactively suggest potential annotations, drawing from its repository of learned data. These automated annotation suggestions aim to streamline the annotation process by anticipating user needs and promoting consistency across the design plan. This feature not only saves time but also enhances the overall quality of the annotations by leveraging the collective intelligence gathered from previous interactions within the platform.

Referring now to FIG. 1B, a high-level diagram illustrates components included in a system 120 that uses AI to generate an interactive and collaborative user interface 125 and programmable apparatus (controller) 123 operative to execute method steps useful in one or both of: adding annotations to design elements within a two-dimensional representation of a design plan, and managing alterations to these design elements while automatically adjusting the associated annotations and rules in real-time. This process may involve identifying design elements that may benefit from additional information or clarification, prompting users to add relevant annotations. Furthermore, when design elements are moved or altered, a controller may be functional to register or otherwise dynamically update related annotations, alter or keep intact the annotation to reflect changes, thereby maintaining accuracy, association, and relevance of the annotations. Simultaneously, the system may enforce automated, predefined, or user-defined rules regarding who can make alterations to those design elements and/or associated annotations, based on user roles and permissions, thereby preserving the integrity of the design plan, and facilitating a collaborative yet controlled design environment.

According to some embodiments of the present invention, a two-dimensional reference 121, such as a design plan, floorplan, blueprint, or other document includes a pictorial representation 122 of at least a portion of a building. The pictorial representation 122 may include, for example, a portable document format (PDF) document, jpeg, PNG, or other essential non-dynamic file format, or a hardcopy document. The pictorial representation 122 includes an image descriptive of architectural aspects of the building, such as, by way of non-limiting example, one or more of: walls, doors, doorways, hallways, rooms, residential units, office units, bathrooms, stairs, stairwells, windows, fixtures, real estate accouterments, and the like.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. Presentation of the two-dimensional reference may include, for example, scanning a hardcopy version of the two-dimensional document into electronic format and transmitting the electronic format to the controller 123 running the AI engine.

According to the present invention, the AI engine may use raw data, manipulated data, interpreted data, new data and data types generated from existing data. Data may include one or more of: text, image, numerical, pixel patterns, polygons, vectors, molecular, neural, digital, and analog data modalities.

AI engine processing may include one more of: converting image data to pixel patterns and/or polygon patterns, manipulating pixel patterns and/or polygon patterns, analyzing pixel patterns and/or polygon patterns, optical character recognition, alphanumeric analysis, symbol recognition and the like. Proposed action strategies, protocols and opportunities may be associated with an ascertained state.

The present invention provides for the deployment of computational frameworks combining disparate aspects of technology to perform tasks that are beyond the ability of traditional design and build systems or human intelligence. These systems aggregate large volumes of disparate data that may or may not be intuitively linked to building design, carbon footprint, eco-friendliness, compliance codes, supply chain availability, anticipated ambient climate conditions, measured ambient climate conditions, building activities, or other data source, and utilize multiple modalities data manipulation, algorithms, and statistical models to generate proposed action strategies for a patient (or group of similarly situated patients). Modalities of data manipulation may include, but are not limited to:

Machine Learning (ML): A subset of AI where systems learn from data. Instead of being explicitly programmed, they adjust their operations to optimize for a certain outcome based on the input they receive.

Deep Learning: A subfield of ML using neural networks with many layers (hence “deep”) to analyze various factors of data, such as for example convolutional neural networks (CNNs) used in image recognition. For example, convolutional neural networks may receive as input image data from scans of various types and generate pixel patterns representative of the scans. The pixel patterns may be compared to a library of other pixel patterns and/or manipulated to emulate progression of a disease state and/or a treatment protocol over time.

Natural Language Processing (NLP): Allows systems to understand, interpret, and generate human language. NLP may provide interpretations of voice data. Voice data may be made accessible, for example, via recording made during design plan review and assessment and/or during supply chain activities.

Robotics: Robots may operate using AI principles, enabling the robots to perform tasks in accurate, specific, and consistent ways. Robots may also be utilized during data collection, such as during building scans (e.g., 3D image acquisition scans), as built measurement acquisition, infrared heat image acquisition and the like.

Knowledge Representation: The methods and apparatus taught herein may receive data in a native or enhanced state and manipulate and transform the received data into a machine learning understandable form.

Reasoning: The methods and apparatus taught herein may solve deploy logical deduction via expert systems and the like to facilitate decision-making.

Perception: The methods and apparatus taught herein may use algorithms and complex relational processes that allow machines to interpret disparate data sets, including image data, sound data, and alphanumeric data.

Apparatus and methods may be arranged to form one or more of: Neural Networks; Genetic Algorithms; Expert Systems; and Reinforcement Learning.

In some embodiments, GPUs may be used to accomplish large-scale machine-learning models using parallel processing capabilities. Hardware accelerators may be utilized for deep learning tasks. In some embodiments, tensor processing units and/or neuromorphic computing mechanisms may be used to analyze data sets. Cloud platforms may be used with AI processes, such as deep learning that require significant computational resources.

Electronic and/or electromechanical apparatus may provide data to be processed using the methods and apparatus presented herein. Apparatus may include, by way of a non-limiting example, one or more of: three-dimensional (3D) image scans, heat imaging acquisition, design plan scanners, building monitoring electronic sensors, drone-based electronic scans, satellite-based data acquisition or other means of acquiring data that may be transformed into digital and/or analog data sets.

The controller is operative to generate a collaborative user interface 125 on a user computing device 126. The user computing device may include a smart device, workstation, tablet, laptop or other user equipment with a processor, storage, and display.

The user interface 125 includes a reproduction of the pictorial representation 122 and an overlay 124 with one or more user-manipulatable components, such as, by way of non-limiting examples: boundaries, line segments, polygons, images, icons, points, and the like. The line segments may have calculated lengths that may be mathematically manipulated and/or summarized. Aspects such as polygons, line segments, shapes, icons, and points may be counted, added, subtracted, extrapolated, and have other functions performed on them.

In addition, renditions of the user interface 125 may be created and saved, and/or communicated to other users, or controllers, compared to subsequent interface renditions, archived and/or submitted to additional AI analysis.

In some embodiments, a first user interface 125 rendition may be modified by a user to create a second user interface 125 and submitted to AI analysis to perform tasks including assisting users in adding better annotations to a selected design element. This assistance is based on the AI's analysis of the selected design element and a historical review of similar annotations associated with such design elements. The AI engine continuously learns from the ways users add annotations to different types of design elements, enabling it to suggest the most relevant and useful annotations for any given element. This learning process allows the AI engine to provide tailored suggestions that improve over time, reflecting the collective experience and insights of the user community on the collaborative platform of the present invention. By leveraging past annotation patterns, the AI facilitates a more intuitive and efficient annotation process, enhancing the collaborative design effort.

Referring now to FIG. 1C, the illustration showcases an exemplary aspect of the present invention's collaborative environment, demonstrating how a user may annotate a design element on a design plan. In this exemplary embodiment, the user interface 125 displays a static pictorial representation 122 of a design plan, containing various dynamic design elements such as lines, polygons, rooms, walls, and boundaries. A user may initiate the annotation process by selecting a design element 130 on the design plan 122, which can be done by marking on or around 131 the desired design element 130 or by simply double-clicking on the design element 130.

Upon selection, a pop-up window 132 appears, providing a space where the user can type in text annotations that will be linked with the chosen design element 130. Alongside the text entry field, the pop-up window 132 may also include an additional options button 134. This button 134, when selected, unveils a suite of annotation tools 135, offering a range of methods to enrich the annotations.

For instance, the user can choose to attach multimedia content 136, like photos or video clips, which may serve as a visual supplement to the textual annotations for the selected design element 130. If the user wishes to add an audio note, they can do so using the audio record function 137, capturing their verbal instructions or comments directly via a microphone. Moreover, the user also has the convenience of using a speech-to-text feature 138, where spoken words are transcribed into written text annotations. This functionality simplifies the process of adding detailed descriptions or instructions, as the user's voice is automatically converted to text and associated with the selected design element 130 as an annotation.

In some embodiments of the present invention, the interactive user interface may be engineered to offer an intuitive mechanism for annotating within a shared design plan. When a user selects a design element, such as a polygon, a line, a room or a wall, the system may respond by presenting a context-sensitive annotation interface. This interface is contextually programmed to suggest annotation tools and options relevant to the type of design element selected. For example, upon selecting an area where an air conditioning unit is to be installed, the interface may prioritize or suggest multimedia annotations that provide visual cues or installation guidelines.

Referring now to FIG. 1D, the diagram illustrates an exemplary feature of the present invention's interface, specifically designed to aid users in the annotation process. The figure displays a user actively engaging with an annotation pop-up window 132 for a selected design element within the collaborative platform. As the user begins to type, for instance, “Install AC Here,” the system's AI engine intervenes with automated annotation suggestions as shown in an automated annotation suggestions window 150.

These suggestions, shown in the automated annotation suggestions window 150, are generated based on a variety of factors, including the current context of the design element, the user's typing activity, and historical data collected from past user interactions with similar design elements. The exemplary annotation suggestions may include but are not limited to: “Install AC Here but size must not exceed . . . “, “Prefer window here . . . “, or other recommendations like “Drawing room-install TV here . . . “. Each suggestion aims to prompt the user with common annotations or considerations that align with the selected design element's purpose and location.

Additionally, the interface may also facilitate inclusion of multimedia annotations, as evidenced by the “Add this image . . . ” option accompanied by a photo icon for a recommended photo extracted from an annotation database to be associated with the annotation. This interactive feature suggests that users can enrich their annotations with visual aids directly related to the selected design element, which may include images or diagrams relevant to the installation or positioning instructions (i.e., annotations) being entered.

This automated annotation suggestions feature showcases the system's dynamic response to user input, effectively marrying the AI's predictive capabilities with the user's manual annotations. It enhances user experience by minimizing repetitive typing, guiding users through a library of common annotations, and providing quick-access options for multimedia attachments. This intelligent assistance is indicative of the platform's design to expedite the annotation process, reduce potential errors, and ensure consistency in documentation throughout the collaborative design environment.

In some embodiments of the present invention, the system's AI engine utilizes an extensive annotation database to provide automated annotation suggestions that may also include a multimedia library. When a user initiates an annotation-adding process for a selected design element, the AI engine queries this library to retrieve and suggest one or more images (or maybe video clips) that are relevant to the design element in question. This library comprises a collection of images and video clips previously used in annotations, which have been tagged and indexed according to the design elements they correspond to.

Furthermore, the AI is capable of generating automated images and video clips based on its historical analysis of similar past annotations. It uses learned patterns and user behavior to predict and present the most pertinent visual aids that could enhance the current annotation. This predictive ability is grounded in the AI's continuous learning process, where it assimilates information from each annotation interaction, gradually refining the relevance and precision of its image suggestions.

Such an embodiment streamlines the annotation process by providing users with quick access to a curated set of images and video clips, reducing the need for manual searches and ensuring a high level of consistency and detail in the annotations associated with specific design elements. Whether the user is specifying installation details, highlighting design features, or indicating modifications, the AI engine's integration with a multimedia library enriches the collaborative experience and aids in the conveyance of clear, concise, and visually supported information.

By way of non-limiting examples, according to the present invention, a design plan may be received as a static image two-dimensional reference. The design plan may be described using lines and arcs, and represent architectural layouts in a simplified geometrical way. In such a representation, architectural elements, such as, by way of non-limiting examples: walls, doors, windows, and architectural details, may be shown using straight lines (for linear elements) and arcs (for curved elements). A floorplan interpreted in terms of lines and arcs and/or patterns of pixels may include one or more of:

Exterior Walls: typically represented by thick lines. The thickness of a line may indicate the wall's thickness.

Interior Walls: which may be shown as slightly thinner lines compared to exterior walls, representing partitions or dividers within a space or other interior area.

Hinged Doors: a straight line representing a door's location and an arc showing the door's swing direction and extent.

Sliding Doors: two parallel lines (representing door panels) may include an arrow or dashed line indicating a sliding direction.

Double Doors: two straight lines representing door panels with arcs indicating each door's swing direction.

Which may, for example, be represented as thin lines or breaks in walls, sometimes with a zigzag line to indicate a window's presence or with a double line indicating a double-pane window.

Straight Stairs: a series of parallel lines showing steps. Often, an arrow may be used to indicate the upward direction.

Spiral Stairs: may be represented using concentric arcs or circles, showing the curvature of the stairwell.

Cabinets, Countertops, Islands: straight lines and arcs may represent a shape and placement of cabinets, countertops, and islands.

Sinks, bathtubs: may typically be represented using a combination of lines and arcs to depict their shapes.

Rounded Corners: instead of sharp, angular intersections between walls, arcs are used to show the curve.

Circular Rooms or Features: may be represented using full circles or arcs.

Electrical: may be shown with dotted lines or specific symbols indicating outlets, switches, and fixtures.

Plumbing: may be represented via dotted or dashed lines to represent hidden plumbing within walls or under floors.

When interpreting or representing a floorplan using lines and arcs, conventions used in architectural drawings may be referenced. In some embodiments, a legend or key that describes what each line, arc, or symbol means, may ensure clarity in understanding the design.

FIG. 1E shows a settings window 140 that emerges when a user engages with the settings option 133 on the annotations pop-up window 132. This settings window 140 serves as a control panel for managing the collaborative and interactive features of the platform tailored to user annotations and design elements.

The “Set Rules” function 141 enables users to establish comprehensive guidelines for managing interactions with the design plan. Users can define protocols for editing, altering, deleting, or relocating both design elements and their associated annotations within the collaborative platform. Serving as a robust governance mechanism, this function ensures that any modifications to the design plan or its components are consistent with predefined conditions. These conditions may be customized to meet the unique demands of a specific project, cater to individual user preferences, align with organizational policies, or comply with applicable safety codes and regulations. Furthermore, the “Set Rules” 141 feature is designed to be flexible, allowing for an automated or manual adjustment of rules as the project evolves or as new information becomes available to the AI engine, ensuring ongoing relevance and adherence to the latest standards and practices.

In some embodiments of the present invention, the settings window may be a nexus of innovative controls that adapt to the intricate dynamics of the collaborative design environment. The “Set Rules” feature 141 may be engineered with an algorithm that can predict and propose rule sets based on the project type, historical data, and individual user performance, thus preempting the need for manual input, and offering a starting point for rule customization. The “Set Rules” option 141 may allow users to construct a detailed matrix of permissions, specifying who can make edits, how elements can be adjusted, and under what circumstances annotations can be moved or deleted. This rule-setting may go beyond general restrictions, offering granular control, such as time-bound editing rights or element-specific permissions that ensure changes are made responsibly and in accordance with the project's lifecycle or phase-specific requirements.

With the “Share with” option 142, users can distribute the annotations and design elements to selected team members or stakeholders. Beyond standard methods like email, the system may incorporate features such as direct in-platform tagging, integration with project management tools for task assignments, or even using unique identifiers like QR codes that, when scanned, grant access to specific annotations or design elements. In some embodiments of the present invention, the “Share with” function 142 may employ machine learning algorithms to suggest potential team members for collaboration based on their past contributions, expertise, and current availability, going beyond manual tagging and email sharing. This feature may integrate with organizational calendars and resource planning tools to automatically suggest the best times and team members for collaborative sessions within the platform.

The “Share with” feature 142 may extend collaboration by integrating with advanced user identification systems, enabling sharing through biometric recognitions, such as fingerprint or retina scans, for high-security projects. It may also incorporate smart notifications that alert users when a relevant component is shared with them, streamlining the review and feedback process.

The “Roles” setting 143 is designed to define and assign specific permissions to different users or team members. This feature not only controls who can change or approve annotations but also can extend to defining hierarchies of approval, enabling tiered levels of access where senior designers or project managers may have override capabilities or exclusive editing rights. In some embodiments of the present invention, for “Roles” setting 143, the system may dynamically suggest role changes for users by analyzing their interaction patterns with the platform. For example, if a user frequently adds substantial contributions to a particular design element, the system may suggest elevating their role for that element or similar elements, streamlining the workflow and empowering effective contributors.

Lastly, the “AI Suggestions” option 144 may provide users with the ability to influence the AI engine's learning path, particularly concerning the relevance of automated annotation suggestions. Users can give feedback on the AI's suggestions to enhance its future performance. For instance, a senior architect might train the AI to recognize and suggest energy efficiency tips for certain design elements, or an engineer might focus the AI's learning on structural integrity notes. Additionally, depending on their authority, users might influence the AI's learning on a personal level for individualized suggestions or on a collective level to improve the engine's utility for the entire team.

In some embodiments of the present invention, the “AI Suggestions” option 144 may include a feedback loop where the AI engine not only learns from the annotations made but also from the user's response to its suggestions, including ignored, accepted, or modified inputs. This allows the AI engine to refine its suggestion accuracy, not just in the context of the current project but across similar future projects. Additionally, the AI engine may offer versioning control suggestions, advising on the ideal moments to create new versions of the design plan, design element and annotations based on the volume and significance of recent annotations and changes.

Referring now to FIG. 1F, an exemplary process is illustrated wherein a user engages with the collaborative platform to relocate a design element 130 which carries an associated annotation 160. Upon moving the design element to a new position, now indicated as 130′, the system's AI engine automatically relocates the associated annotation to 160′ associated with the moved design element 130′, maintaining the contextual link between the annotation and the design element.

In some embodiments, the AI engine is equipped to not only move the annotation but also to assess and implement slight adjustments to the annotation's content or presentation. These modifications may be based on factors such as the nature of the movement, the final placement of the design element, or the spatial relationship to other design elements and annotations. For example, if a window, originally on the north-facing wall, is moved to a south-facing wall, the annotation may be updated to reflect the change in sunlight exposure.

Additionally, the AI engine may provide visual cues to indicate that an element has been moved, such as highlighting the original and new locations or creating a trail from the original to the new position. In some other embodiments, the AI engine may suggest updates to related annotations based on the element's new location, such as recommending changes in material or dimensions that permit the structure or building to be compliant with fire and/or safety standards.

Furthermore, the system may track the movement history, allowing users to view and revert to previous positions if needed. This feature supports iterative design processes where relocation decisions are explored and evaluated in real time. It may also aid in maintaining a comprehensive audit trail that can be helpful during the review stages or in post-project analyses.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; complexity of features (e.g. a number of angles or curves included in a perimeter of an area; a type of hardware that may be used to construct a portion of a building, a quantity of a type of hardware that may be used to construct a portion of the building; or other variable value.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). Other features may be removed, such as the text 208, the plumbing features and other internal appliances and furniture which may be shown on drawings used as input to the processing. Again, such feature recognition may be useful to accomplish other goals, but for a goal of boundary 211 definition that delineates a floorplan 210 as illustrated in FIG. 2B a pictorial representation may be purposefully devoid of such features, as illustrated.

Referring now to FIG. 2B, a boundary 211 is illustrated around a grouping of defined spaces 213-216. Spaces are areas within a boundary (which may include but are not limited to rooms, hallways, stairwells etc.).

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. Boundaries that include polygons are useful, for example in creating a three-dimensional representation of a design plan.

According to the present invention, a boundary may be represented on a user interface as one or both of: one or more line segments, and one or more polygons. In addition, a feature may be represented as a single point, a polygon, an icon, or a set of polygons. In some embodiments, a point may be placed in a centroid position for the feature and the centroid points may be counted, summarized, subtracted, averaged, or otherwise included in mathematical processes.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. Extrapolation of a two-dimensional reference into a three-dimensional representation may be supported with a boundary that includes polygons.

In one embodiment of the present invention, the AI engine is adept at analyzing a two-dimensional representation of a floor plan to identify and generate a selectable array of editable components, such as walls, doors, and fixtures. These dynamic elements are then presented in an interactive user interface, where users can effortlessly select specific design elements to add annotations or to modify those elements directly.

The AI's analytical prowess ensures that these selections and subsequent modifications are intelligently integrated within the overall design framework, enabling a fluid and intuitive design alteration experience that supports real-time collaboration and planning accuracy.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Typical units referenced in a scale include inches: feet, centimeters: meters, or any other appropriate unit.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length.

Referring now to FIG. 2C, a user interface 220 is illustrated with multiple regions 221-224. The multiple regions 221-224 may be presented via different hatch representations or other distinguishing pattern (in some embodiments regions may also be represented as various colors etc.). During training of AI engines, and in some embodiments, when a submitted design drawing includes highly customized or unique features, a user may wish to adjust an automated identification of boundaries and automated filling of space within the boundaries.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, or change an aspect of polylines, polygons, arcs, circles, ellipses, splines, NURBS or predefined subsets of the interface. The user can thereby “correct” an assignment error made by the AI engine, or simply rearrange aspects included in the interface for a particular purpose or liking.

In some embodiments, modifications and/or corrections of this type can be documented and included in training datasets of the AI model, also in processes described in later portions of the specification.

Discrete regions may be regions associated with an estimation function. A region that is contained within a defined wall feature may be treated in different ways such as ignoring all areas within a boundary, to counting all areas within a boundary (even though regions do not include boundaries). If the AI engine counts the area, it may also make an automated decision on how to allocate the region to an adjacent region or regions that the region defines.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. Regions with similar dominance ranks may share space, or regions with higher dominance ranks may be automatically assigned to a boundary. In general, a dominance ranking schema will result in an area being allocated to the space with the higher dominance rank. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified. In some embodiments, the incorporation of a dominance rank may facilitate the delivery of automated suggestions for the revision of design plans. The dominance rank may serve as a strategic guide, steering the focus towards regions (or design elements) of higher dominance rank. For instance, regions with a higher dominance rank are recommended to remain as unchanged as possible in the suggested revisions besides making sure that the revised designs of the regions comply with the safety codes. The annotation process related to the selected design elements or dynamic components may also be presented based on the dominance rank of regions, dynamic components representing the regions, and the selected design elements on the design plans. This approach scrutinizes the annotations added to the regions or design elements with a higher dominance rank on the overall design, ensuring that modifications align with both regulatory requirements and the foundational elements that contribute significantly to the design's integrity.

In some embodiments, an area 235A between interior boundaries 236-237 and an exterior boundary 235 may be fully assigned to an adjacent region 232-234. An area between interior boundaries 235A may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. Parameters may also be based upon items that are automatically counted using AI analysis of pixel patterns that identify a pattern as an item, such as, by way of non-limiting example, one or more of: doors or other paths of egress; plumbing fixtures; fixed obstacles; stairs; inclines; and declines.

In some examples, a boundary 235-237 and associated area 235A may be allocated to a region 232-234 according to an allocation schema, such as, for example, an area dominance hierarchy, to prioritize a kitchen over a bathroom, or a larger space over a smaller space. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region as illustrated in FIG. 2D. In various embodiments, different calculated features are included in a user interface floorplan model 231 such as features representing aspects of a wall, such as, for example, center lines, the extent of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence annotation process as discussed above for FIG. 1A.

Once boundaries have been defined a variety of calculations may be made by the system. A controller may be operative to perform method steps resulting in calculation of a variable representative of a floorplan area, which in some embodiments may be performed by integrating areas between different line features that define the regions.

Alternatively, or in addition to method steps operative to calculate a value for a variable representative of an area, a controller may be operative to generate a value for element lengths, which values may also be calculated. For example, if ceiling heights are measured, presented in drawings, or otherwise determined, then volume for the room and surface area calculations for the walls may be made. There may be numerous dimensional calculations that may be made based on the different types of model output and the user-inputted calibration factors and other parameters entered by the user.

In some embodiments, a controller may be provided with two-dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross-sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects.

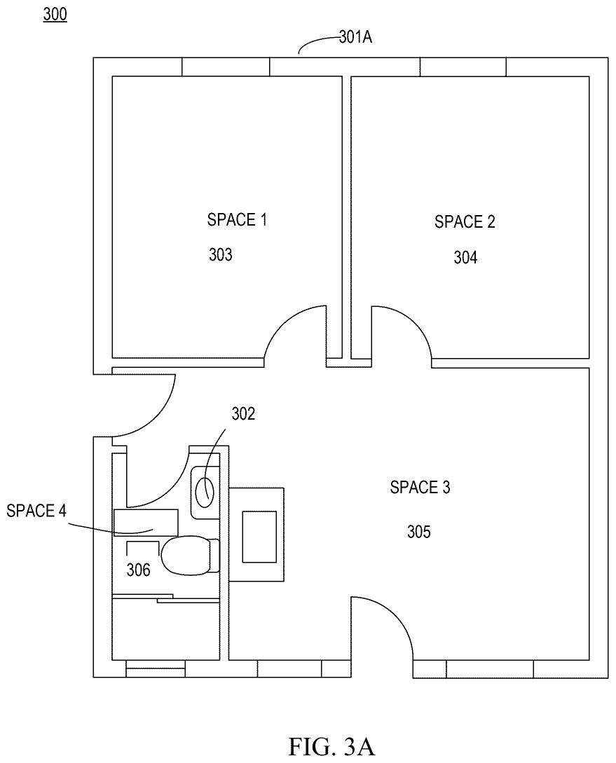

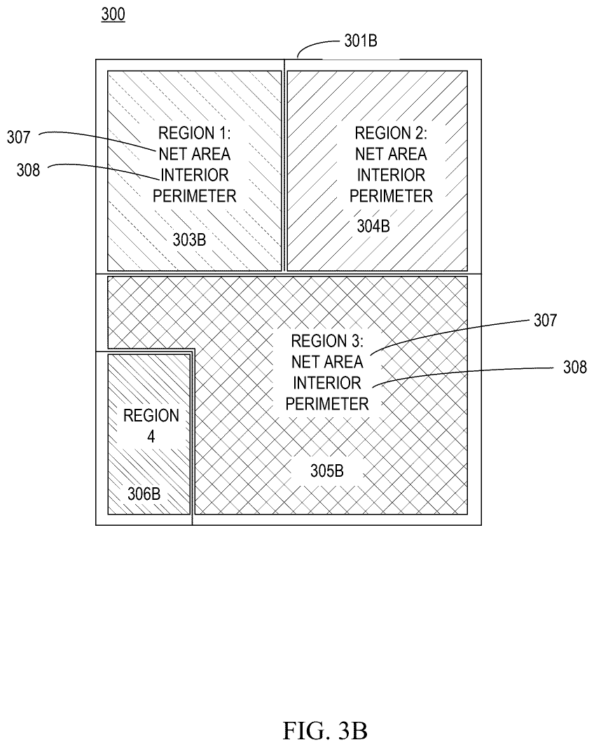

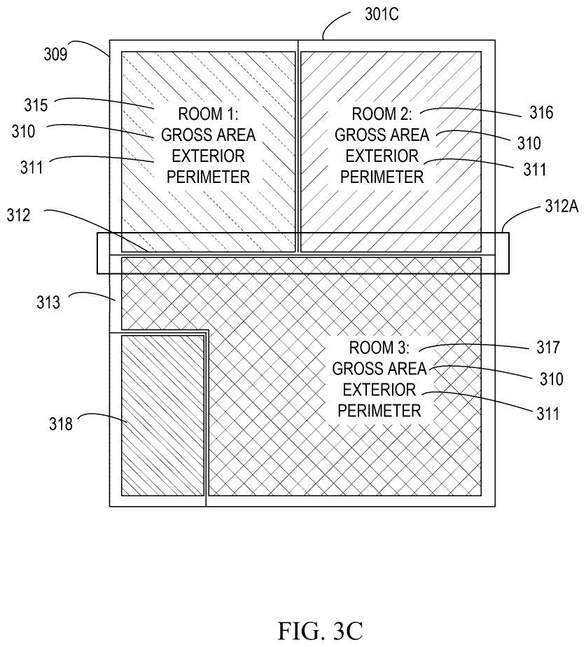

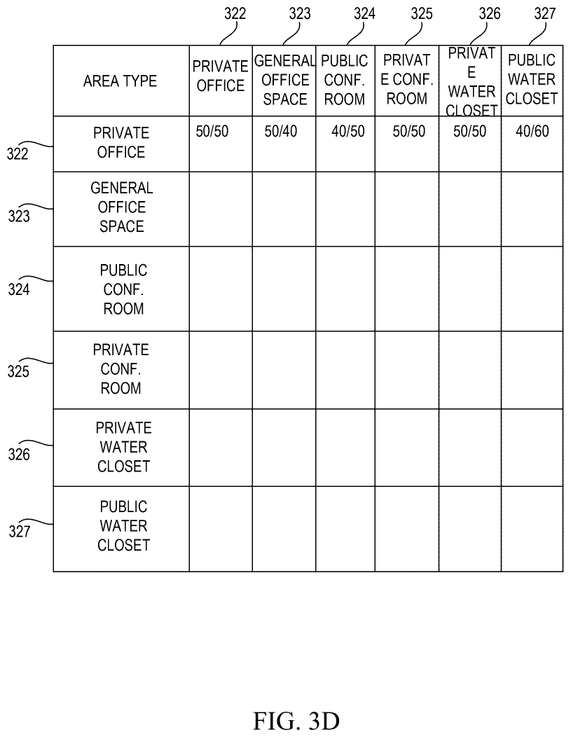

Referring now to FIGS. 3A-3C a user interface 300 may generate multiple different user views, each view has different aspects related to the two-dimensional reference drawing inputted. For example, referring now to FIG. 3A, a user interface 300 with a replication view 301A may include replication of an original floor plan represented by a two-dimensional reference, without any controller-added features, vectors, lines, or polygons integrated or overlaid into the floorplan. The replication view 301A includes various spaces 303-306 that are undefined in the replication view 301A but may be defined during the processes described herein. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. The controller may generate a tally of multiple fixtures 302 identified in the two-dimensional reference. The tally of multiple fixtures 302 may include some or all of the fixtures identified in the two-dimensional reference and may be used to generate an estimate for completion of a project illustrated by, or otherwise represented by, the two-dimensional reference.

Referring now to FIG. 3B, in the user interface 300 a user may specify to a controller that one of multiple views available is to be presented via the interface. For example, a user may designate via an interactive portion of a screen displaying the user interface 300 that a region view 301B be presented. The region view 301B may identify one or more regions and/or spaces 303B-306B identified via processing by a controller, such as for example via an AI engine running on the controller. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a kitchen area and wallboard associated with Region 4 may be designated as needing to be fireproof material.

Referring now to FIG. 3C, a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space but may be less useful to an occupant than a net interior area 307 and interior perimeter 308. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior).

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms.

In some embodiments, the present invention calculates an area bounded within a series of polygon elements (such as, for example, using mathematical principals or via pixel counting processes), and/or line segments.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like.

These views may be used in generating estimation analysis documents. Estimation analysis documents may rely on fixtures, region area, or other details. By assisting in generating net area, estimation documents may be generated more accurately and quickly than is possible through human-engendered estimation parameters.

With reference now again to FIGS. 3B and 3C, regions 303B-306B defined by an AI engine may include one or more Rooms in FIG. 3B subsequently have regions assigned as “Rooms” in FIG. 3C.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example, adjacent areas (e.g., area 315 and area 317 or area 317 and area 318), the hierarchical relationship may be used to generate a dominance ranking of one area over another area, or to ascertain factors useful in one or both of: annotating a design element or modifying a design element. For example, a dominance ranking may allocate space used to calculate one or more of: an occupancy load; a width and/or area of an egress path; a width and/or area of a common path; a length of a dead-end; egress capacity; and travel distance from a furthest point. In this context, regions assigned a higher dominance ranking are designated to be inherently associated with elevated safety standards.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ratio, but a private office adjacent to a general office space may be allocated 60 percent of an area included in a border region, and so on.

Dominance associated with various areas or regions may be systemic throughout a project, according to customer preference, indicated on a two-dimensional reference by two-dimensional reference basis or another defined basis.

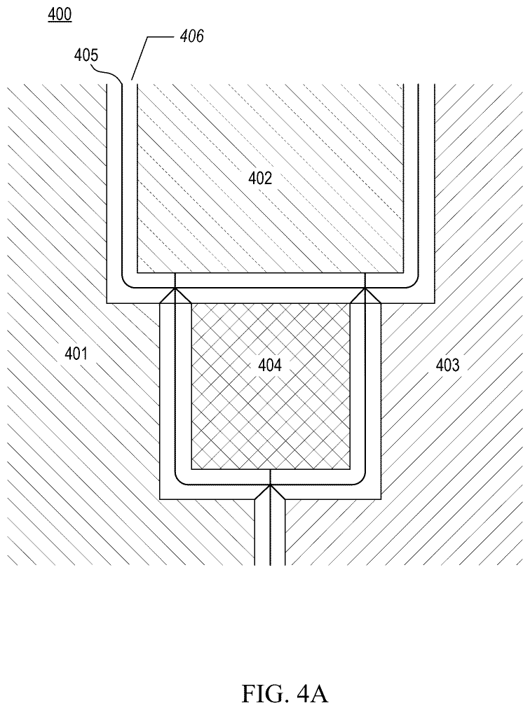

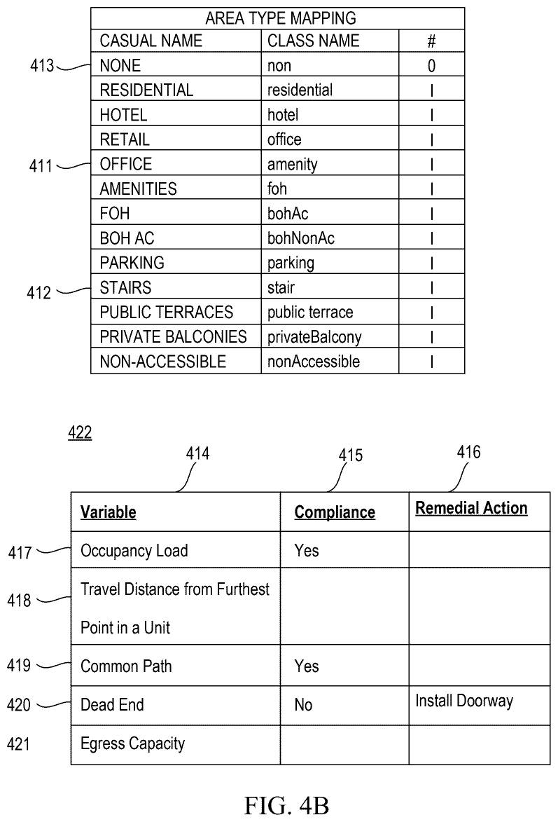

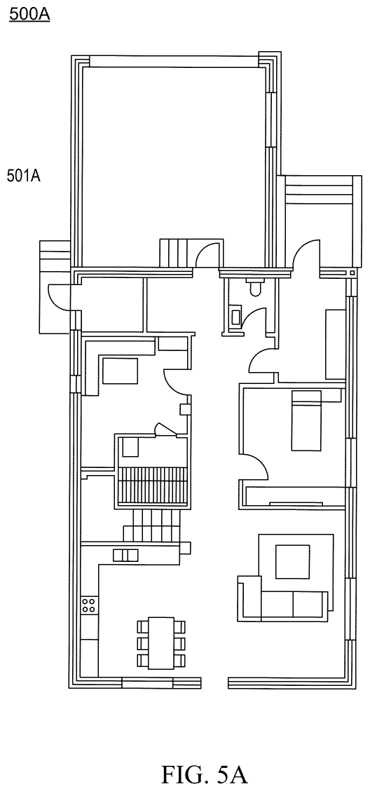

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. Different classes or types of spaces or areas may be scored to be equal to, dominant (e.g., above) others or subservient (e.g., below) others.

Referring now to FIG. 4B, an exemplary table A indicating classes of space types and their associated ranks. In some embodiments, a controller may be operative via execution of software to determine relative ranks associated with a region on one or either side of a boundary. For example, area 402 may represent office space and area 404 may represent a stair-well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect one or more of: one or both of: annotating a design element, modifying a design element, or modifying a physical version of the design element. For example, as illustrated, variables 417-421 may include occupancy load 417, travel distance from a furthest point 418, Common path 419, dead end 420, and egress capacity 421.

The determination of boundary definitions for a given inputted design plan, which may be a single drawing or set of drawings or other image, has many helpful uses and aspects as has been described. However, it can also facilitate a supportive process executed by a controller, such as an AI algorithm to take boundary definitions and area definitions and generate classifications of a space. As mentioned, this can be helpful to support processes executed by a controller that assigns boundary areas based on dominance of these classifications.

Classification of areas can also facilitate further aggregations of space. In a non-limiting example, accurate automatic classification of room spaces may allow for a combination of all interior spaces to be made and presented to a user. Overlays and boundary displays can accordingly be displayed for such aggregations. There may be numerous functionalities and purposes for automatic classification of regions from an input drawing.

An AI engine or other process executed by a controller may be refined, trained, or otherwise instructed to utilize a number of recognized characteristics to accomplish area classification. For example, an AI engine may base predictions for a type “/” category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of recognized text may provide direct evidence upon which to infer a decision. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces may allow a training set to train a relevant AI engine to classify a space with added accuracy. Furthermore, certain space classes may typically fall into ranges of areas which also may aid in the identification of a region's class. Accordingly, it may be helpful to influence the makeup of training sets for classification that contain common examples of various classes as well as common variations on that theme.

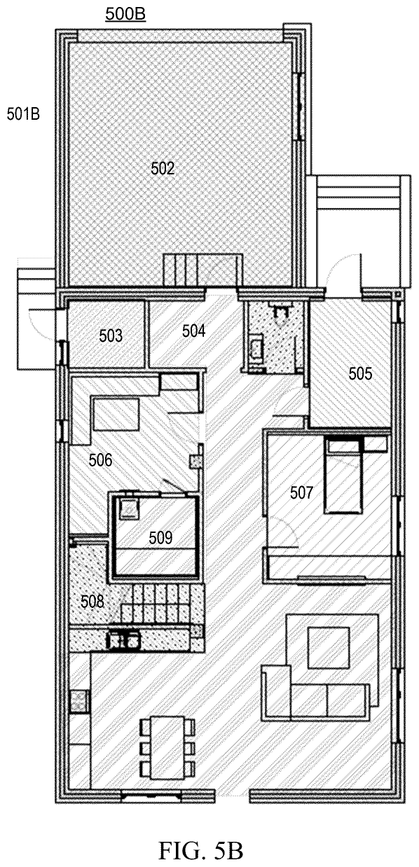

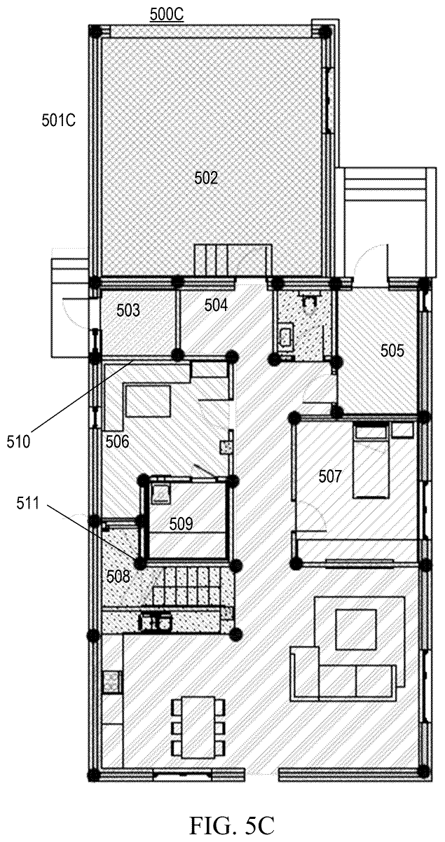

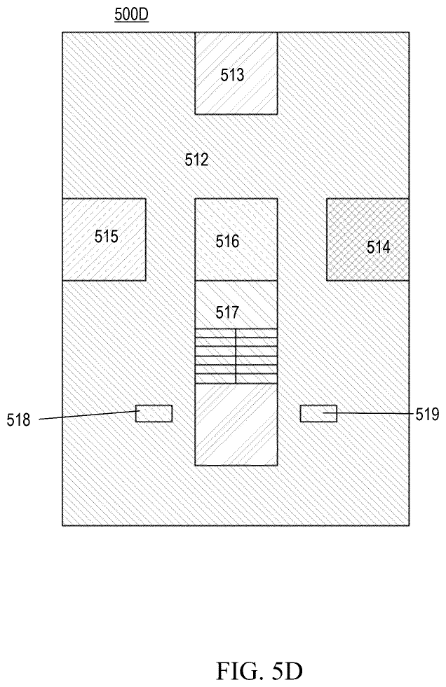

Referring now to FIGS. 5A-5D, a progressive series of outputs that may be included in various user interfaces are illustrated and provides examples of a recognition process that may be implemented in some embodiments of the present invention. Referring now to FIG. 5A, a relatively complex drawing of a floorplan may be input as a design plan 501A into a controller running an AI engine. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all: of regions; spaces; patterned portions; line segments; polygons; symbols; icons or other portions of the user interfaces may be assembled and presented in a user output and our user interface, or as input into another automated process. In some embodiments, selection or marking of the desired segments or design elements may be incorporated on the user interfaces 500A-500D as shown in FIGS. 5A-5D.

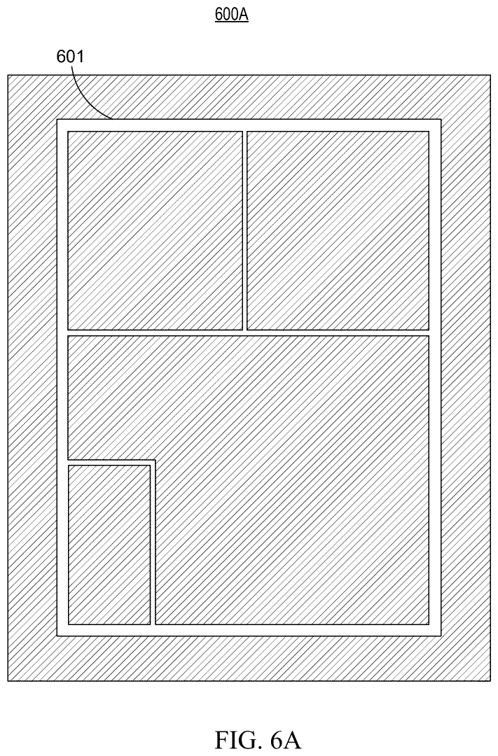

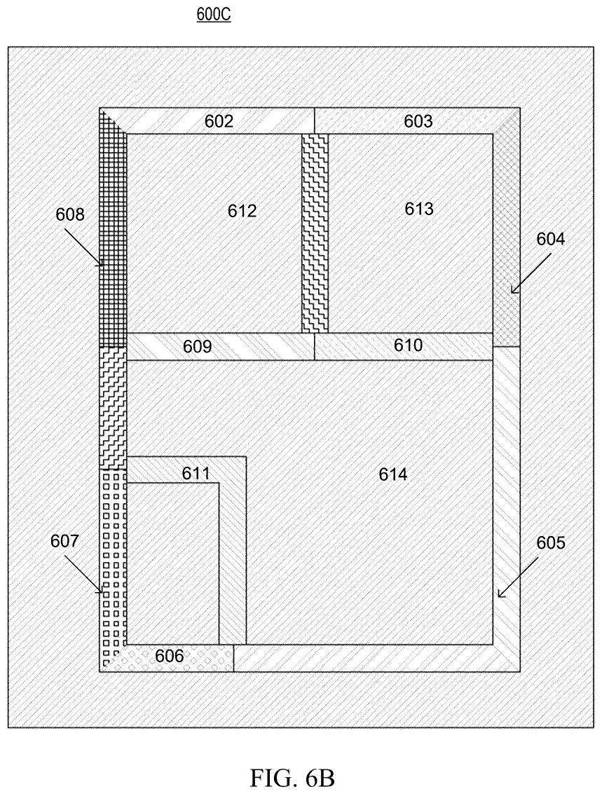

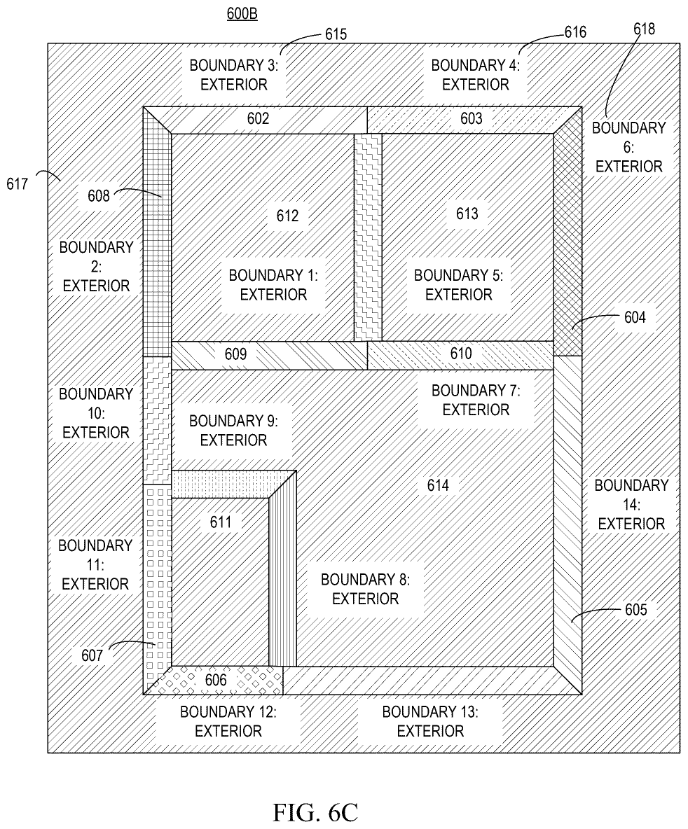

Referring now to FIGS. 6A-6C, in some embodiments, automated and/or user-initiated processes may include refinement of regions, spaces, or areas may involve one or both of a user and a controller identifying individual wall segments 211A from previously defined boundaries.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C.

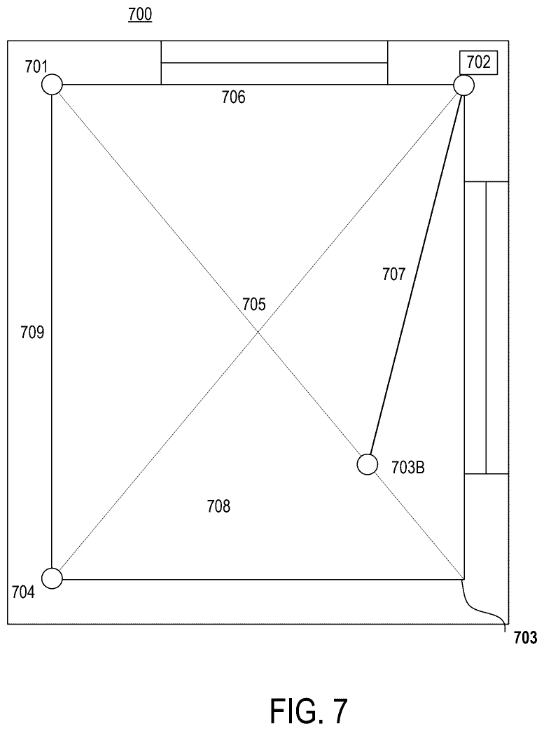

Referring now to FIG. 7, in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance. Additionally, in some embodiments, user interaction involving positioning of a vertex 701-704 may comprise selection of a desired segment or design element in a design plan by marking and combining a plurality of vertex points similar to vertex 701-704.

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to complete a project.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

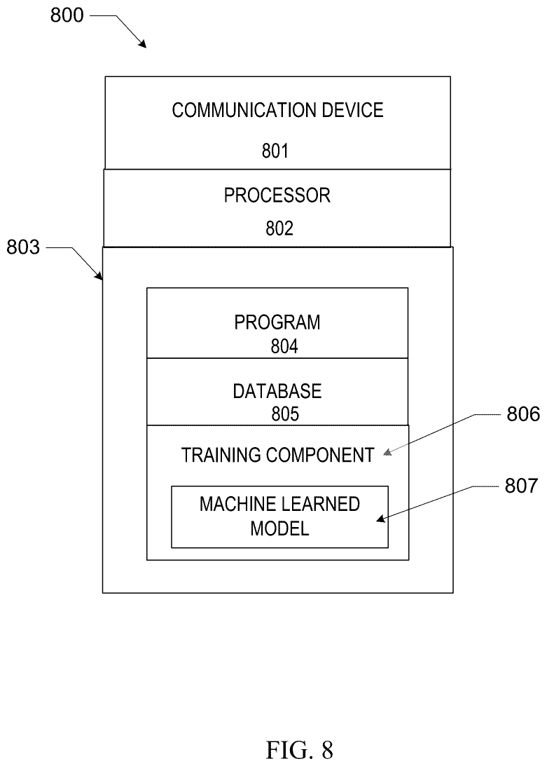

Referring now to FIG. 8, an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine-learned models 807.

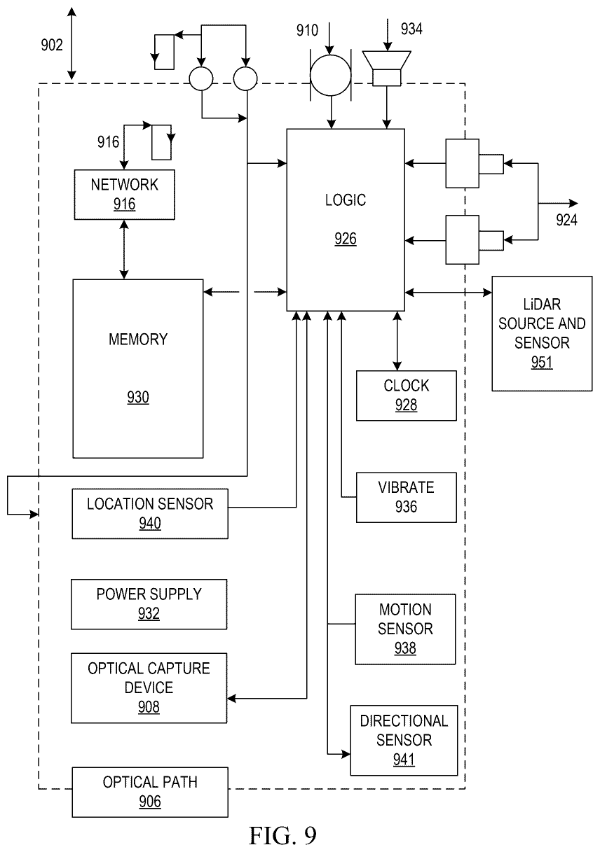

Referring now to FIG. 9, a block diagram of an exemplary mobile device 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. The microphone 910 may also be utilized by users to provide audio annotations (or for speech-to-text annotations) of the present invention. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments, other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LIDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record time and strength of returned signal that is reflected off of surfaces in the environment of the mobile device 902. In some embodiments, as have been described herein, a 2-dimensional drawing or representation may be used as the input data source and vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBic. Features in the BIM or CAD datafile may already have defined boundary aspects having innate definitions such as walls and ceilings and the like. An interactive interface may be generated that receives input from a user indicating a user choice of types of innate boundary aspects a user provides instruction to the controller to perform subsequent processing on.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determine classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

In some embodiments, the user may be given access to movement of boundary elements and vertices of boundary elements. In examples where lines or vectors are used to represent boundaries and surrounding areas, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a feature, or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

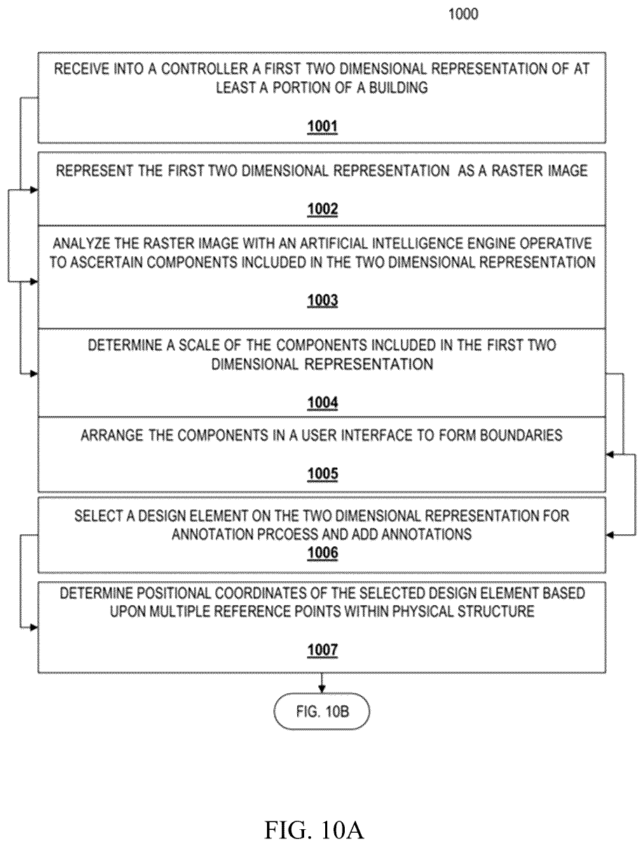

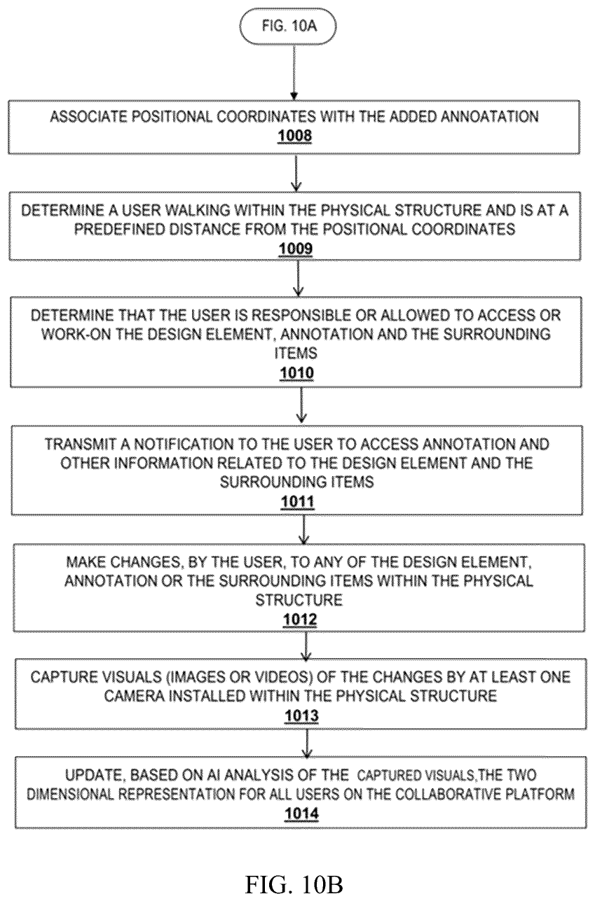

Referring now to FIGS. 10A-10B method steps are illustrated for enhancing code compliance related annotation process in design plans with some exemplary intelligent functionalities. At step 1001, the method includes receiving into a controller a design plan (or a first two-dimensional representation) of at least a portion of a building. As described above, the design plan may include an architectural drawing, floor plan, design drawing and the like.

At step 1002, the portion of a design plan (or a first two-dimensional representation) may be represented as a raster image or other image type that is conducive to artificial intelligence analysis, such as, for example, a pixel-based drawing.

At step 1003, the raster image may be analyzed with an artificial intelligence engine that is operative on a controller to ascertain components included in the design plan.

At step 1004, a scale of components included in the design plan may be determined. The scale may be determined, for example, via a scale indicator or ruler included in the design plan, or inclusion in the design plan of a component of a known dimension.

At step 1005, a user interface may be generated that includes at least some of the multiple components i.e., design elements.

At step 1006, following the generation of the user interface that showcases various design elements, the method involves selection of a particular design element within the two-dimensional representation for annotation purpose. Users can add annotations directly onto the selected design element to specify details, instructions, or other relevant information.

At step 1007, the AI engine then determines the positional coordinates of the selected design element, utilizing multiple reference points whose precise location is either known or can be determined by the AI engine. This enables precise location tracking within the design plan, ensuring that annotations are accurately placed in relation to the physical space within the physical structure.

In some embodiments of the present invention, the method may include utilizing a set of predefined reference points within a two-dimensional representation of a building to establish positional coordinates for newly selected design elements on the two-dimensional representation. These reference points are distinguished locations or markers on the design plan itself for which positional coordinates are already known or have been previously marked.

When a user selects a design element to annotate, the AI engine analyzes the spatial relationship between the selected design element and the established reference points. By calculating distances, angles, and relational positioning with respect to these known coordinates of the reference points, the AI engine accurately determines the positional coordinates for the selected design element.

For instance, the reference points could be key structural components such as doorways, corner junctions of walls, or fixed installations like elevators or staircases that are unlikely to change over time. These stable elements may serve as location reference points in the AI's spatial analysis to determine positional coordinates for the selected design element.

The AI engine may employ algorithms similar to those used in triangulation methods, where the known positions of reference points are used to deduce the location of the newly selected design elements. This may also be akin to geospatial techniques used in mapping, where a series of known coordinates provide a framework for plotting new points.

In some embodiments of the present invention, the process of determining positional coordinates for the selected design elements within a two-dimensional representation may significantly be enhanced by leveraging physical components (reference points) installed within the actual building structure. These reference points, embedded within the physical infrastructure, serve as locational beacons for the system's AI engine.

The reference points may be sophisticated IoT devices with unique identifiers, which are strategically placed at intervals throughout the building. Their locations, known to the system, are utilized by the AI to calculate the positional coordinates of a selected design element. This may be achieved through techniques akin to indoor positioning systems (IPS) which use the signal strength, signal angle, and time-of-flight of the signals between the known reference points (or sensors) and the selected design element.

At step 1008, the method further includes associating the positional coordinates with the added annotation, creating a virtual geo-referenced anchor point that links the annotation content with its spatial context in the building (physical structure).

At step 1009, the system may incorporate user location tracking to determine if a user, perhaps walking within the physical structure, is within a predefined proximity to the positional coordinates associated with the annotation and the selected design element. This proximity-based interaction may enable context-aware notifications and actions.

At step 1010, it is determined whether the user has the responsibility or the authorization to access or work on the design element, annotation, and surrounding items, establishing a layer of security and access control within the system.

At step 1011, the system transmits a notification to the user to access annotations and other information related to the design element and surrounding items. This notification may serve to streamline the workflow and help the user to install, service, or move the design element or surrounding items.

In some embodiments of the present invention, the system may integrate environmental sensors that detect occupancy or movement of users, enabling the AI engine to determine user presence proximate to the virtual geo-referenced anchor point of the design element or annotation and notify annotations relevant to the user's current location. This can be particularly useful in large-scale buildings where navigating to specific points for inspection or work can be challenging.

At step 1012, users with the appropriate permissions can make changes to any of the design elements, annotations, or surrounding items within the physical structure, enabling live updates and modifications.

At step 1013, the system captures visuals, such as images or videos, of the changes made at step 1012 within the physical structure. This step bridges the gap between the physical modifications and their digital representations.

Finally, at step 1014, an update is made, based on AI analysis of the captured visuals, to the two-dimensional representation for all users on the collaborative platform. This sophisticated feature enables the system to reflect real-world changes in the virtual design space, effectively synchronizing the digital plan with the physical state of the building.

For example, if a wall is moved or a new window is installed, the system not only registers the change but also revises the digital floor plan accordingly. This revision may involve updating the positions of walls in the digital model (design plan), recalculating room areas, and adjusting lighting or ventilation annotations based on the new window placement.

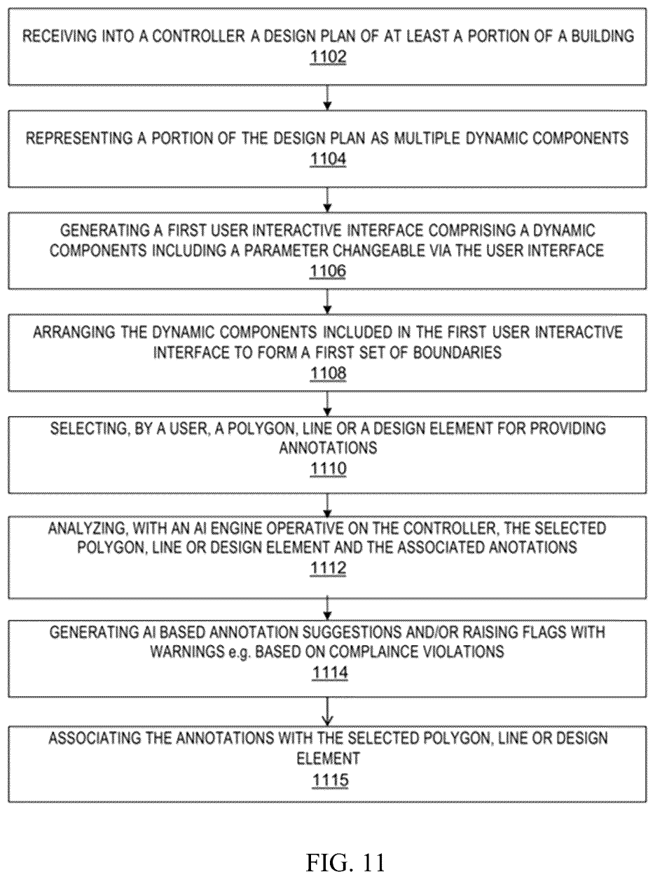

Referring now to FIG. 11, a system including one or more controllers (comprising AI engine) can be configured to perform particular operations or actions by virtue of having executable software, firmware, hardware, or a combination of them that in operation cause the controllers to be operative to perform method steps for annotating design elements, and analyzing annotations for providing automated annotation suggestions and for determining non-compliance to safety codes or predefined rules within a collaborative environment.

At step 1102, receiving into a controller a design plan of at least a portion of a building.

At step 1104, the method may include representing a portion of the design plan as multiple dynamic components.

At step 1106, the method may include generating a first user interactive interface including at least some of the multiple dynamic components representing a portion of the design plan, each dynamic component including a parameter changeable via the user interactive interface.

At step 1108, the method may include arranging the dynamic components included in the first user interactive interface to form a first set of boundaries, the first set of boundaries including a respective length and area, and the first set of boundaries defining at least a portion of a first unit.

At step 1110, the user selects a design element within the first user interactive interface. This design element may be a polygon representing a room, a line indicating a boundary, or any specific feature on the design plan that is open to amendment with further detail, installation instructions, or clarification. The selection process is intuitive, allowing users to simply click or tap on the desired element within the interface. Other ways to select the design elements are also discussed in various embodiments of the present invention.

At step 1112, once a design element is selected, the AI engine operative on the controller analyzes the selected design element and its associated annotations. This analysis includes understanding the spatial context of the design element, its dimensions, the implications of its location, and any previously associated annotations or data. The AI uses this analysis to inform and enhance the subsequent steps of the annotation process.

At step 1114, the AI engine generates annotation suggestions, which can include text, images, and multimedia elements. These suggestions are based on a database of best practices, user preferences, past annotations, and compliance with safety codes. These suggestions can be similar to the past annotations to the similar design elements or AI generated suggestions based on machine learning past annotations. For example, if a window (design element) is selected, the AI engine may suggest annotations related to glazing options, energy efficiency ratings, or aesthetic design considerations. Moreover, if the system detects potential non-compliance with safety codes or predefined rules based on the selected element's attributes or the annotations, it may raise flags with warnings, prompting the users to adjust the design or update the annotations accordingly.

At step 1115, the system further associates the annotations with the selected design element. This association ensures that the annotations are correctly positioned relative to the element and are displayed within the user interface in a manner that other users (possibly with appropriate permissions) can easily understand and interact with.

Some embodiments of the present invention enable the collaborative platform to serve not just as a static repository of design plans but as a dynamic, intelligent system that guides users through the annotation process, helps maintain compliance, and facilitates a more efficient design workflow. For instance, upon selecting a staircase element (design element), the system may suggest annotations regarding tread depth standards, highlight potential accessibility issues, or even propose alternative designs that are better suited to the overall building layout. This intelligent guidance may serve to streamline the collaborative process, making the system invaluable to architects, engineers, and other stakeholders involved in the design and building process.

In some embodiments of the present invention, the system's capabilities extend beyond the creation and management of annotations within design plans. The AI engine, through an integrated and responsive user interface, may offer intelligent equipment recommendations based on selected design elements, annotations context, or modifications within the design plan.

Upon selection of a design element for annotation or modification, the AI engine may analyze the context and specifics of the change, such as the function of the space, dimensions of the design element, or materials specified in annotations. Leveraging this information, the AI may then suggest equipment(s) that is optimally compatible with the design requirements. These suggestions may include a variety of equipment(s) from different brands, along with detailed pricing information.

The system may also integrate with third-party vendor databases to pull real-time pricing and availability data, providing users with a possible comprehensive shopping experience within the platform. Users can review these recommendations, compare options, and even access reviews or ratings within the same interface.

For example, if a user annotates a design element to convert a space into a high-traffic area, the AI engine may recommend durable flooring options available from specific brands and present the cost implications directly within the interface. If the annotation specifies the need for an eco-friendly HVAC system, the system might suggest several models that meet the latest environmental standards, complete with efficiency ratings and prices.

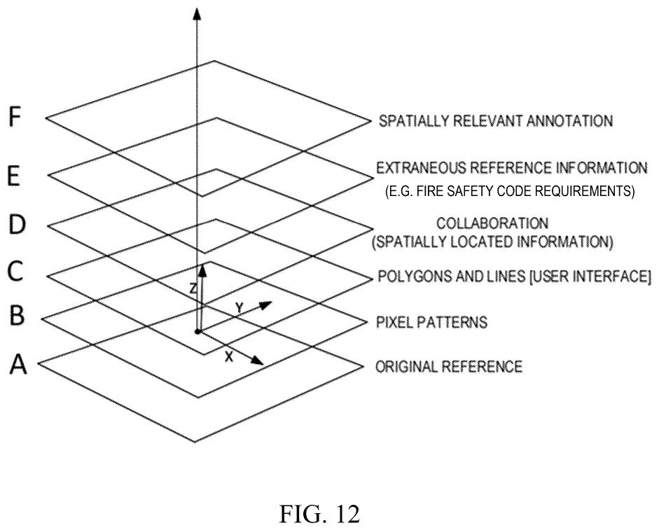

Referring now to FIG. 12, a conceptual framework showing multiple layers involved in the AI-powered collaborative system for code compliance related annotations of a design plan, represented as levels A through F.

Level A represents the foundation where an original reference, such as an architectural drawing or floor plan, is received into the system. This original reference serves as the baseline two-dimensional representation from which the subsequent analytical and collaborative processes are built.

Progressing to Level B, the system transforms the original reference into pixel patterns. This conversion is helpful, as it facilitates the subsequent AI analysis. Each pixel can be seen as a data point that the AI uses to discern shapes, lines, and other design elements within the design plan.

At Level C, these pixel patterns are organized into dynamic elements on the user interface. This may include arrangement of polygons and lines which delineate design elements and boundaries within the user interface, enabling a visual and interactive representation of the design plan.

Level D illustrates the collaboration layer of the system. It is here that the collaborative platform becomes operational, allowing multiple users to interact with the same design plan. This layer supports real-time sharing and modification of the plan, fostering a cooperative workspace where users can contribute, edit, and update the design simultaneously.

Level E expands the functionality by integrating various standards and compliance protocols. It may also connect to third-party platforms, which can for example: one or more authorities having jurisdiction.

Finally, Level F embodies the final level of interaction within the system. It enables comprehensive user engagement with the design elements (dynamic components, polygons, lines, walls, rooms, boundaries etc.). Users can select design elements to annotate, define rules and roles for team members, share design plans and annotations, approve, or propose modifications, and more. The AI engine at this level provides automated annotation suggestions, ensuring adherence to fire safety codes and other compliance standards. It also facilitates sending of notifications to relevant team members, perhaps based on their proximity to the design element in question or their role in the project.

For example, when a user annotates a wall to indicate the need for fireproofing, the AI engine may suggest specific materials that meet fire safety standards. If a material is selected, the AI may then automatically update compliance status of that portion of a design plan.

In some embodiments of the present invention, the collaborative platform allows users to share a selected portion of the design plan with other users for collaborative efforts such as modifications, updates, or changes to both design elements and their associated annotations. This sharing capability facilitates coordinated project management and facilitates equal access to the latest design iterations for all team members. When a user selects a segment of the design plan, they can easily distribute it to other stakeholders, who can then review, suggest alterations, or directly make changes within their areas of expertise.

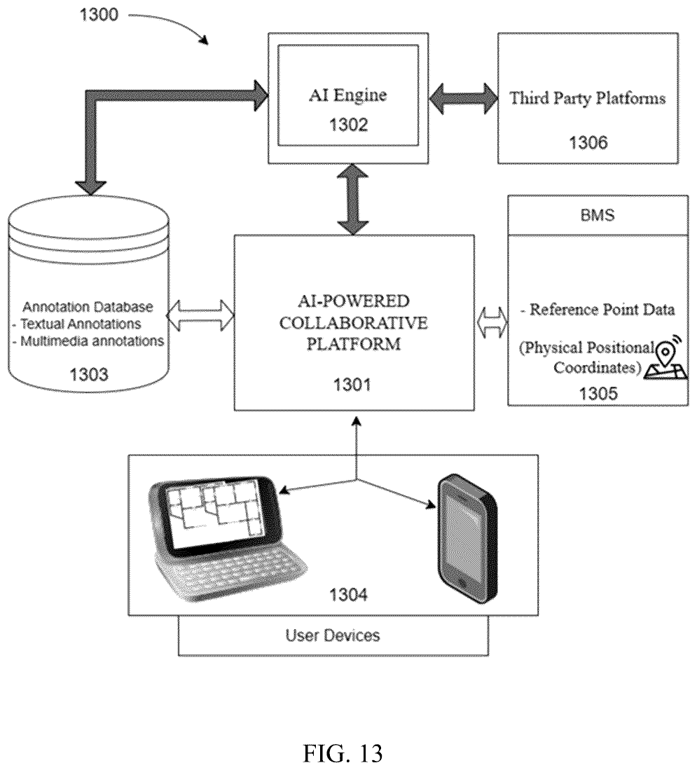

FIG. 13 illustrates some exemplary components that may be included in an AI-powered collaborative platform 1301, designed to revolutionize the architectural, engineering, and construction industries through enhanced collaborative capabilities.

At the heart of system 1300 is the AI Engine 1302, which processes vast amounts of data, learns from user interactions, and delivers intelligent, context-aware suggestions. It is a dynamic component that continuously evolves, becoming more sophisticated with each annotation, modification, or interaction carried out by users.

An annotation database 1303 is a comprehensive repository that houses textual annotations and multimedia annotations. These are not just static entries but serve as a knowledge base for training the AI Engine 1302. The database 1303 also enables the AI engine 1302 to provide automated, precise annotation suggestions and to learn the nuances of various project types and user preferences.

In some embodiments of the present invention, the AI Engine 1302 leverages the comprehensive annotation database 1303, which is an aggregation of past textual and multimedia annotations, to refine and enhance its suggestion capabilities. This learning process involves the AI Engine 1302 analyzing patterns, keywords, and contexts from the stored annotations to understand the types of annotations that are typically associated with various design elements. As users interact with the system, the AI Engine 1302, drawing upon this historical data, suggests automated annotations that are relevant to the current design element being reviewed or modified. It can recommend textual annotations that have been frequently used in similar contexts or generate new annotations, both textual and visual (images or video clips), that are informed by the collective intelligence embedded within the annotation database 1303. This process not only speeds up the annotation phase by providing users with a repository of potential annotations to choose from but also ensures consistency in documentation and adherence to best practices that have been established over the lifecycle of numerous projects.

Third party platforms 1306 represent an extended ecosystem connected to the AI Engine 1302, encompassing vendors for supplies, labor marketplaces for staffing needs, compliance authorities for safety codes, brand catalogs for equipment and fixtures, and advertising platforms for targeted product placements. This integration allows for a seamless procurement process, labor management, and equipment selection directly from the collaborative platform.

A building management system (BMS) 1305 allows the collaborative platform 1301 to track changes within the physical building, adjust design plans accordingly, and ensure that the annotations remain accurate and up-to-date.

The AI Engine 1302 employs advanced image recognition algorithms and machine learning techniques to identify any deviations or alterations from the established digital design plan. When changes are detected, ranging from structural modifications to repositioning of design elements, the AI Engine 1302 automatically updates the digital representation of the design plan to mirror the altered reality within the physical building. This ensures that the digital design plan remains a living document, accurately synchronized with the building's physical evolution. The updated design plan can then be used to inform stakeholders, guide further development, and serve as a reliable reference for maintenance and operational purposes.

The BMS 1305 also incorporates a sophisticated network of reference location points, installed a various locations in the physical building, which provide a high level of accuracy in determining positional coordinates of selected design elements on the design plan.

Smart devices 1304, such as laptops, tablets, or smartphones, can connect to the AI-powered collaborative platform 1301. They enable users to access design plans, annotate, perform modifications, share updates with other team members, receive notifications, and delve into details of design elements.

For instance, a user on a construction site can use a tablet to scan a QR code on a newly installed component, which may bring up the design plan on the platform. The AI Engine 1302 may then display relevant annotations, suggest modifications based on the latest BMS data, or even pull up installation videos from the Annotation Database 1303.

In some embodiments of the present invention, the system may be equipped with an integrated proximity detection feature that enhances on-site workflow efficiency.

Upon recognition of the user's proximity to the specified location, the AI Engine 1302 triggers an immediate response. A notification is sent to the user's device, potentially with a prompt to access detailed information. This notification may include a direct link that opens up the relevant section of the digital design plan on the user's device, highlighting the annotations and presenting any associated instructions or multimedia guides. This may be especially useful for installation processes, safety checks, or quality inspections, where immediate access to the detailed plans and notes can significantly streamline on-site tasks.

Furthermore, as users interact with the design plan through their devices, the AI Engine 1302 can learn their preferences, for example, automatically suggesting a particular brand of fixtures known to meet the user's quality standards or cost targets, based on previous selections stored in third party platforms 1306.

Furthermore, the system may provide a sustainability index score by analyzing the selected equipment and materials against fire safety standards, giving users insight into the safety compliance of their choices and the potential for green building certifications.

By encompassing these features, the embodiment underscores the platform's role not just as a design tool but as a helpful component of the project management ecosystem, streamlining workflows from conceptual design to the final stages of construction and installation.

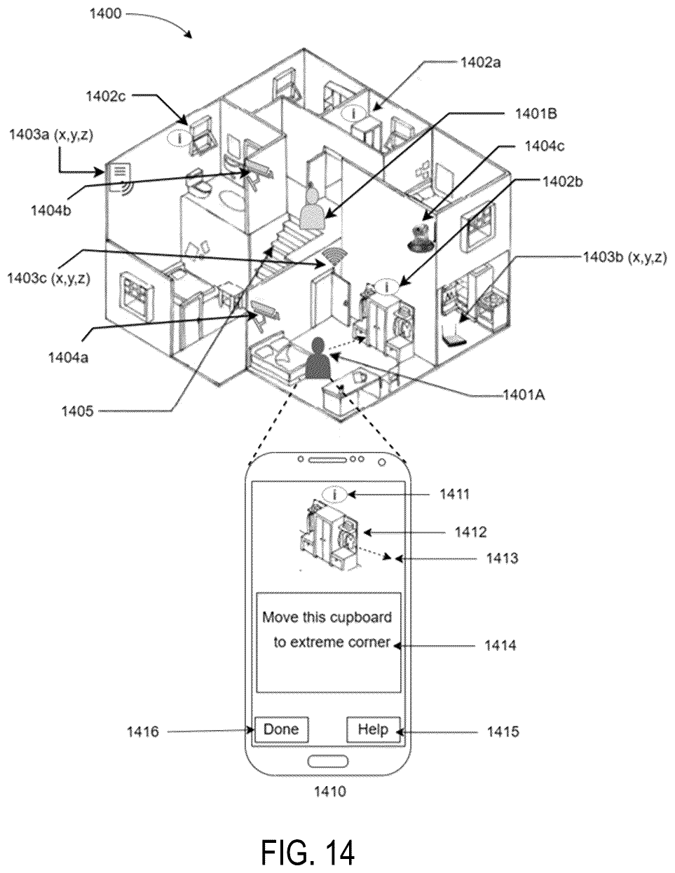

Referring now to FIG. 14, a comprehensive visualization of the interactive and integrated nature of the AI-powered collaborative platform or environment as it operates in integration with a physical building structure 1400. This figure depicts a scenario where the physical building environment, users, and the digital realm of the design plan converge through advanced technological orchestration.

In the physical building structure 1400, users 1401A and 1401B, each equipped with their respective user devices 1410, are navigating the space within the physical building structure 1400. These users (1401A, 1401B) may be professionals, perhaps a construction manager, a technician, an electrician or any authorized user, whose movements within the building 1400 are tracked using a network of installed location reference points (1403a-1403c) having known (X, Y, Z) positional coordinates. These reference points (1403a-1403c) create a mesh of locational data, which facilitates the ability to account for the location of personnel, at any given moment, within the building's ecosystem.

Annotated physical components (1402a-1402c) within the building 1400, such as a cupboard 1402b, a bookshelf 1402a, and a ventilation unit 1402c, are annotated on the design plan with specific annotations that detail installation instructions, maintenance schedules, or compliance notes.

In some embodiments of the present invention, the reference points (1403a-1403c) are more than mere beacons; they are carefully positioned nodes with specified location coordinates, creating a virtual grid across the physical structure 1400. This grid facilitates the mapping out of the space within the physical structure 1400, as it allows for the precise determination of the positional coordinates, on the x, y, and z axes, of any annotated component, such as a cupboard 1402b, within the design plan. When someone adds an annotation to a component like a cupboard 1402a, these reference points provide the positional coordinates data needed to anchor (tag positional coordinates) that annotation accurately within both the digital design plan and the physical realms. This precise coordination facilitates that annotations are not only relevant but also exactly placed, bridging the gap between the design intent and the actual construction space.

As user 1401A approaches the cupboard 1402b, their proximity (i.e., predefined distance from an annotated design element on the design plan or from an annotated physical component such as cupboard 1402b) triggers an action within the platform. A notification is promptly delivered to their mobile device 1410. This notification may showcase an image 1412 of the cupboard 1402b, along with an annotation icon 1411, enabling the user 1401A to access, review, or modify the existing annotations. Accompanying this visual prompt is an annotation description portion 1414 of the required action for example: “Move this cupboard to the extreme corner,” detailed in the original annotation associated with the cupboard 1402b (design element selected on design plan), coupled with an indicative arrow 1413 which points towards the suggested new location for the cupboard (guiding user on how to perform the required action).

Should the user 1401A require additional information or assistance, the ‘Help’ option 1415 is available, offering a deeper dive into the design plan, the nature of the annotations, or a step-by-step guide on how to execute the task. If the user 1401A has completed the action or updated/changed the annotation, they can select the ‘Done’ button 1416 to confirm task completion, which in turn updates the project status on the platform. This may notify a team manager or other stakeholders that the task has been carried out as per the directive, prompting a review or approval process if necessary.

The AI Engine 1302 is programmed to recognize changes in the physical structure 1400 by comparing the real-time visual data against the existing digital design plan. When a discrepancy due to a change, such as the relocation or alteration of the cupboard 1404b, is detected, the AI Engine processes this information and automatically updates the digital design plan to reflect the new physical reality.

This dynamic updating ensures that the digital design plan remains an accurate reflection of the physical building structure at all times, allowing for an up-to-date reference for future modifications, maintenance, or planning.

The platform's ability to deliver relevant information in situ revolutionizes traditional task management and completion verification processes. It effectively reduces the likelihood of errors, accelerates the execution of tasks, and ensures compliance with design specifications. The inclusion of a user feedback loop, through the ‘Help’ and ‘Done’ buttons, not only streamlines task resolution but also captures valuable data that can be used to optimize workflows, enhance user training, and refine the AI's predictive capabilities.

FIG. 14 thus portrays a dynamic and responsive construction management ecosystem where every component, from the physical installation to the digital annotation and user interaction, is interconnected to create a cohesive, intelligent workspace. This system does not just react to user actions; it proactively guides them, demonstrating the present invention's commitment to a smart, integrated, and user-centric design and construction process.

In some embodiments of the present invention, the platform facilitates dynamic adjustments within the two-dimensional design representation by allowing for the movement of design elements from one location to another, ensuring that any associated annotations are concurrently relocated to preserve spatial accuracy. This capability is mirrored in the physical realm as well, where modifications to the positioning of design elements within the actual building structure are directly reflected in the two-dimensional representation. When a physical version of a design element is repositioned, the system automatically updates its virtual counterpart and associated annotations in the design plan.

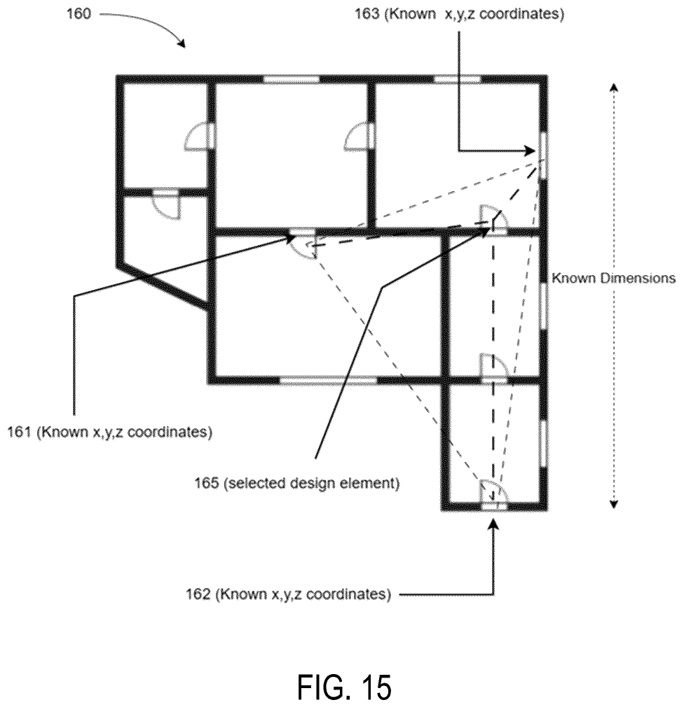

Referring now to FIG. 15, an exemplary application of the present invention, where a two-dimensional representation 160 of a design plan, incorporates predefined (known) positional coordinate markers for two or more design elements within an architectural layout. In this instance, 161, 162, and 163 symbolize distinct dynamic components (design elements), each with their own marked x, y, z coordinates on the design plan, representing a sophisticated level of spatial definition within the digital model.

These known coordinate markers are scanned from the design plan and may function as reference points within the design plan. When a user selects a new design element 165 (maybe for annotation process), which does not have predetermined coordinates, the system applies geometric triangulation methods to deduce its positional coordinates. Using the positional coordinates of 161, 162, and 163 dynamic components, the system calculates the relative distances and angles to the selected design element 165, determining its exact location within the architectural space. This process of triangulation may incorporate advanced algorithms that account for the known dimensions of the space, further refining the accuracy of the positional data.

This capability is particularly beneficial when precise spatial positioning is required for new installations or modifications within a pre-existing structure and for sending notification alerts to a user physically walking proximate to the physical version of the selected design element within the building. For instance, if the selected design element 165 represents the intended location for a new lighting fixture, understanding its exact position is crucial for planning electrical routes and ensuring that the fixture is harmoniously integrated into the building's aesthetics and functional grid. Proximate to to the physical version of the selected design element may include, for example, within a direct line of sight of a user, within range of contact by the user, within range of audio perception to the user, or within a distance enabling one or more of the five sense of the user to perceive the design element.

Additionally, the ability to calculate precise positional data for new design elements based on established reference points streamlines the design process, facilitating more accurate planning and implementation. This system mitigates potential discrepancies between the design plan and actual execution, ensuring that all components of the building are positioned as intended, thereby maintaining the integrity of the architectural design.

This detailed representation within the digital design plan, when combined with real-world data, forms a robust digital twin of the physical space, allowing architects, engineers, and builders to visualize, plan, and execute with a high degree of precision and confidence.

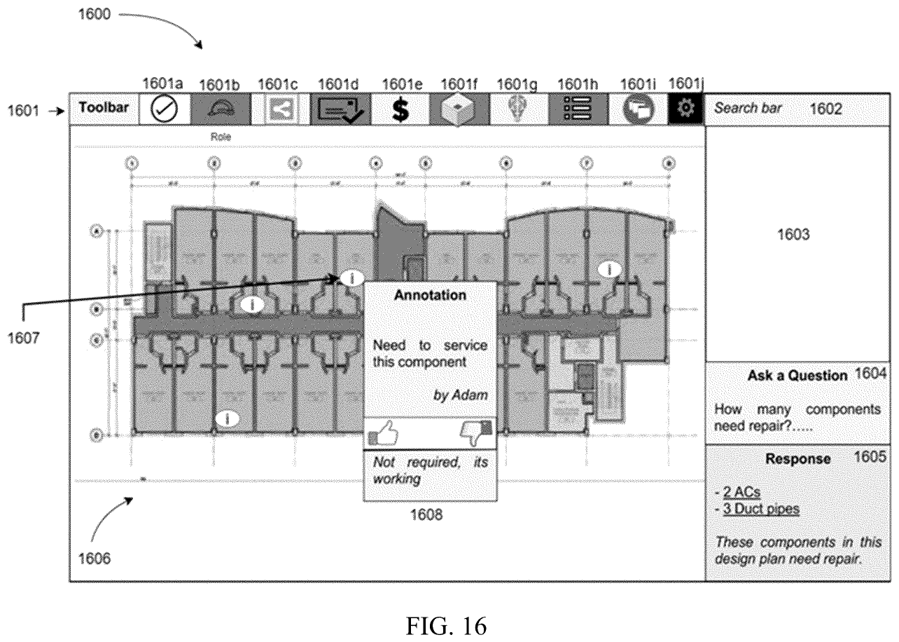

Referring now to FIG. 16, an exemplary interactive & collaborative user interface 1600 of an AI-powered system designed to optimize the code compliance related annotation process for construction and design projects. The interface 1600 shows a design plan 1606 adorned with various dynamic components. Many of these dynamic components (design elements) may comprise a respective annotation icon 1607, indicating that those elements have been annotated on the current design plan. These icons, when clicked, prompt an annotation window 1608 to appear, providing details such as the nature of the annotation, the contributor's identity, and options for interaction, including the ability to like, dislike, or comment. Such user interactions may be used by the AI engine, which learns from this engagement to either automatically validate (approve or disapprove) annotations or offer intelligent annotation suggestions in future annotation processes.

A search bar 1602 is a powerful feature on the interface 1600, enabling users to quickly locate specific elements of the design plan within the collaborative platform (environment). For instance, team members can input search queries such as “completed walls,” “remaining electrical fittings,” or “pending plumbing sections,” and receive instant results (within section 1603), making it a helpful tool for project tracking and management.

Further, in a question section 1604, users can inquire about various aspects related to the design plan, such as queries regarding the details of certain design elements or clarification on annotation particulars. The AI engine meticulously analyzes these questions against the design plan, dynamic components, annotations, and associated data, providing prompt, accurate automated responses 1605, thus effectively acting as an intelligent assistant.

A toolbar 1601 offers an array of tools (1601a-1601j) for comprehensive project management and design interaction. A ‘Select’ option 1601a, for instance, allows for the precise selection of design elements for annotation or modification and the sharing of specific plan segments or sections with other team members or stakeholders. Tool 1601b displays the roles and responsibilities assigned to team members, enhancing clarity in project management and task delegation. The tool 1601b may offer possibility to assign or change roles of the team members and see who are responsible for which task.

A ‘Share’ option 1601c facilitates distribution and sharing of design plan sections, design elements, or associated annotations with other stakeholders or team-members, ensuring collaborative continuity. With check compliance option 1601d, users can review compliance status of various government compliances and identify any breaches of safety codes or project rules, ensuring that the project adheres to all regulatory standards.

Cost management may be handled by tool 1601e, where users can access real-time cost estimations, modify budgets, and manage compliance issues directly within the platform. Tool 1601e may be operative to give users immediate insight into the compliance impact of various aspects of the design plan.

Moreover, if a project manager wants to explore the fire and safety repercussions of adding an additional floor to a building, tool 1601e can promptly adjust the estimated safety implications and additional resources needed. It enables users to play with different scenarios and see how each decision affects the compliance of the design plan.

Another feature 1601f allows for 3D visualization and navigation of a design plan, further enriched by code compliance aspects.

A tool 1601i serves as an annotation center, where users can review all annotations and respond to any assigned tasks, while tool 1601j houses customizable settings options, allowing users to tailor the interface to their preferences and requirements.

Each of these features may be operative to support the workflow, from initial planning to final execution, ensuring the platform remains a central hub for coordination, communication, and management throughout the lifespan of a construction project.

In some embodiments of the present invention, an AI-powered collaborative platform is provided for code compliance related annotation process within architectural and construction projects. Initially, a controller receives a detailed two-dimensional representation of a building's design plan. An AI engine, integral to this system, delves into the representation, identifying various architectural elements and their spatial arrangements as depicted through a complex pattern of pixels. This initial analysis lays the groundwork for an interactive user interface that showcases these elements, making them ready for user interaction and annotation.

Users engage with this interface, selecting design elements to annotate, thereby infusing the digital blueprint with valuable insights and specifications. The AI engine plays a helpful role, determining the precise spatial coordinates of each annotated element, effectively bridging the gap between digital annotation and physical reality. These annotations are dynamically linked to their corresponding elements, ensuring real-time updates across the collaborative environment for all participants.

Further sophistication is introduced as the platform accommodates the movement of both digital and physical versions of design elements. When an element's position is adjusted within the building's layout or the actual construction site, its associated annotations are automatically realigned within the two-dimensional representation, maintaining an unwavering accuracy and relevance of the project documentation.

An innovative question-and-answer feature empowers users to inquire about various project aspects directly through the interface. Leveraging the latest data, including recent changes or updates, the AI engine responds with precise, automated answers, effectively serving as an intelligent assistant.

Through the integration of third-party platforms, the system extends its utility beyond mere annotation. It facilitates compliance checks, and even AHJ approvals, streamlining project management tasks and ensuring adherence to relevant standards and regulations.

In some embodiments of the present invention, the method additionally comprises determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments, dynamic components may include a polygon and/or arcuate shape. A method of practice of the present invention may further include the steps of: receiving an instruction via the user interactive interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via a user interactive interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in construction of the building. In addition, a type of labor associated with at least one of the items to be included in construction of the building may be designated based upon AI analysis of the first two-dimensional reference (i.e., first design plan) and the second two-dimensional reference (i.e., second design plan), respectively.

Methods of practice may additionally include the steps of: determining whether a design plan received into the controller includes a vector image, and if one of the first and the second design plans received into the controller includes a vector image, converting at least a portion of the vector image into a raster image. Implementations of the described techniques may include hardware, a method or process, or computer software on a computer-accessible medium.

A dynamic component may include a line segment and/or vector, and the method may further include the steps of: receiving an instruction via the user interactive interface to modify a parameter of the line segment and/or vector and modifying the parameter of the line segment and/or vector based upon the instruction received via the interactive user interface. The modified parameter may include a magnitude of the line segment and/or vector and/or a direction of the vector.

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

Still further, in some embodiments, the controller may assess how assignment of different classes of space to one or more designated areas may alter conformance of a design with a specified code. Furthermore, in some embodiments, particular attributes of a building may be analyzed based upon laws or regulations in effect within a geopolitical boundary encompassing the building. In some embodiments, multiple disparate user interfaces may be used to communicate calculated parameters associated with determined attributes.

There may be alternative methods of receiving data from various sources that can be used to generate a design or to supplement a design created in the manners as have been described previously. For example, the system may receive an architectural file with intelligent features of various kinds which will be discussed in further detail following. The present system may operate in concert with a BIM or CAD design system, for example, as an add-in to these design systems and then the present system may have access to design elements, location data and the like directly. In other examples, the present system may access BIM or CAD design system data by loading data files from said systems. In still further examples, the present system may operate to capture data from display screens that are displaying designs from the said BIM or CAD design systems. As an additional example, the present compliance assessment system exhibits its versatility by harmoniously integrating with prominent design frameworks like BIM or CAD. This integration facilitates a proactive approach to evaluate the compliance of building designs in the nascent or initial stages of the creative process, considering an array of potential safety codes. This early-stage assessment not only ensures that the design in progress aligns with regulatory standards but also serves as a strategic time-saving measure, optimizing the efficiency of the overall design workflow. Synergy between compliance analysis and design systems not only enhances the precision of the evaluation at early stages, but also contributes to a more streamlined and resource-efficient architectural and engineering endeavour.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

### Glossary:

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to function as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Building Information Modeling” sometimes referred to as “BIM,” as used herein.

“Vector File” as used herein a vector file is a computer graphic that uses mathematical formulas to render its image. In some embodiments, a sharpness of a vector file will be agnostic to size within a range of sizes viewable on smart devices and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The terms “design plan,” “building plan,” “building design,” “floor plan,” “two-dimensional reference,” “two-dimensional representation,” or simply “design” are used interchangeably, often referring to the same or similar concepts in the context of architectural or construction documentation.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### CONCLUSION

A number of embodiments of the present disclosure have been described. While this specification contains many specific implementation details, they should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood the drawings, and the detailed description thereto, are not intended to limit the present disclosure to the form disclosed, but to the contrary, the present disclosure is to cover all modifications, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous. Nevertheless, it will be understood that various modifications may be made without departing from the spirit and scope of the claimed disclosure.

What is claimed is:

1. A method for code compliance related annotation of a design plan in an AI-powered collaborative environment, the method comprising the steps of:
a. receiving into to a controller a code to be considered during assessment of the design plan;
b. receiving, into the controller, a first two-dimensional representation of the design plan of at least a portion of a building to be analyzed for compliance with the code;
C. with the controller, ascertaining multiple design elements comprising one or more of: architectural aspects, walls, rooms, polygons, lines, and boundaries included in the first two-dimensional representation and represented as a pattern of pixels in a raster image;
d. generating an interactive and collaborative user interface comprising at least some of the multiple design elements, each of the multiple design elements including a parameter changeable via the interactive and collaborative user interface;
e. selecting, by a user, at least one design element from the multiple design elements for annotation process and providing, by the user, an annotation to the user-selected at least one design element;
f. determining, by an AI engine, positional coordinates of the user-selected at least one design element and associating the determined positional coordinates with the user-selected at least one design element; and
g. updating, in real-time, the first two-dimensional representation with the user-provided annotation and the associated positional coordinates to ensure synchronicity across the AI-powered collaborative environment for all users.

2. The method of claim 1 additionally comprising the step of: generating a raster image of the first two-dimensional representation of the design plan; and with an AI engine operative on the controller, analyzing the raster image representing the first two-dimensional representation to generate the interactive and collaborative user interface comprising the multiple design elements.

3. The method of claim 2, wherein determining, by the AI engine, the positional coordinates of the user-selected at least one design element comprises determining the positional coordinates of the user-selected at least one design element based on at least one of: multiple location reference points installed within a building's physical structure, or known positional coordinates of the multiple design elements marked on the first two-dimensional representation.

4. The method of claim 2, further comprising a step of: determining, by the AI engine, positional coordinates (x, y, z) of the user-selected at least one design element based on AI analysis of the raster image, wherein the raster image comprises the multiple design elements with marked positional coordinates.

5. The method of claim 3, further comprising a step of: associating the determined positional coordinates of the user-selected at least one design element with the user-provided annotation.

6. The method of claim 1, further comprising providing, by the AI engine, automated annotation suggestions to the user while the user is providing the annotation to the user-selected at least one design element.

7. The method of claim 1, wherein determining the positional coordinates of the user-selected at least one design element further comprises Cartesian Coordinates.

8. The method of claim 1, further comprising a step of: enabling other users, through the interactive and collaborative user interface, to interact with the user-provided annotation, including one or more options to like, dislike, comment on, or approve the annotation, fostering a dynamic collaborative workflow.

9. The method of claim 7, further comprising a step of: learning, by the AI engine, from user interactions with the user-provided annotation to automatically generate annotation suggestions for future annotation processes.

10. The method of claim 2, further comprising updating the first two-dimensional representation when a physical change to a physical version of a design element is noted within the building.

11. The method of claim 10, wherein the physical change is detected by an authority having jurisdiction.

12. The method of claim 11, wherein proximity is determined based on positional coordinates of an annotated design element.

13. The method of claim 12, wherein a notification comprises actionable links that facilitate immediate viewing or modification of the annotation and the design element.

14. The method of claim 2, wherein the interactive and collaborative user interface includes a 3D visualization option for the design plan, allowing the users to navigate the design plan in three dimensions.

15. The method of claim 1, further comprising prioritizing, by the AI engine, annotations for taking actions by the users based on detected severity of annotations, guiding the users to address critical issues first, wherein the severity of annotations is automatically detected by the AI engine based on AI analysis of the annotations.

16. The method of claim 9, further comprising a step of: dynamically adjusting the user-provided annotation in response to modifications to the user-selected design element and to a physical version of the user-selected design element.

17. The method of claim 1, wherein the AI-powered collaborative environment supports real-time collaborative annotations and modifications by multiple users.

18. The method of claim 1, wherein the AI engine compares the user-provided annotation or user-selected design elements against an integrated database of safety codes or standards to identify a non-compliance.

19. The method of claim 1, further comprising automatically alerting users when the AI engine identifies any non-compliance issue, the method further comprising providing suggestions for compliance adjustments.

20. The method of claim 1, further comprising integrating at least one third-party platform for integrating code compliance services.

21. An apparatus for code compliance related annotation of a design plan in an AI-powered collaborative environment, comprising:
a controller configured to receive a code to be considered during assessment of the design plan;
a processor configured to receive a first two-dimensional representation of the design plan of at least a portion of a building to be analyzed for compliance with the code;
an AI engine operative on the processor to ascertain multiple design elements comprising one or more of: architectural aspects, walls, rooms, polygons, lines, and boundaries included in the first two-dimensional representation and represented as a pattern of pixels in a raster image;
a user interface configured to display at least some of the multiple design elements, each of the multiple design elements including a parameter changeable via the user interface;
a selection module configured to allow a user to select at least one design element from the multiple design elements for annotation and to provide an annotation to the user-selected at least one design element;
a coordinate determination module configured to determine positional coordinates of the user-selected at least one design element and associate the determined positional coordinates with the user-selected at least one design element; and
a synchronization module configured to update, in real-time, the first two-dimensional representation with the user-provided annotation and the associated determined positional coordinates to ensure synchronicity across the AI-powered collaborative environment for all users.

22. The apparatus of claim 21, further comprising a rasterization module configured to generate a raster image of the first two-dimensional representation of the design plan, wherein the AI engine is configured to analyze the raster image to generate the user interface comprising the multiple design elements.

23. The apparatus of claim 21, wherein the coordinate determination module is further configured to determine the positional coordinates of the user-selected at least one design element based on at least one of: multiple location reference points installed within a building's physical structure, or known positional coordinates of the multiple design elements marked on the first two-dimensional representation.

24. The apparatus of claim 21, wherein the AI engine is further configured to provide automated annotation suggestions to the user while the user is providing the annotation to the user-selected at least one design element.

25. The apparatus of claim 21, wherein the coordinate determination module is further configured to determine the positional coordinates of the user-selected at least one design element using Cartesian Coordinates.

26. The apparatus of claim 21, further comprising an interaction module configured to enable other users, through the user interface, to interact with the user-provided annotation, including one or more options to like, dislike, comment on, or approve the annotation, fostering a dynamic collaborative workflow.

27. The apparatus of claim 26, wherein the AI engine is further configured to learn from user interactions with the user-provided annotation to automatically generate annotation suggestions for future annotation processes based upon an analysis of the design plan.

28. The apparatus of claim 21, further comprising an update module configured to update the first two-dimensional representation when a physical change to a physical version of a design element is noted within the building.

29. The apparatus of claim 28, wherein the update module is further configured to detect the physical change by an authority having jurisdiction.

30. The apparatus of claim 21, wherein the user interface includes a 3D visualization option for the design plan, allowing the users to navigate the design plan in three dimensions.

31. The apparatus of claim 21, wherein the AI engine is further configured to prioritize annotations for taking actions by the users based on detected severity of annotations, guiding the users to address critical issues first, wherein the severity of annotations is automatically detected by the AI engine based on AI analysis of the annotations.

32. The apparatus of claim 21, wherein the AI engine is further configured to dynamically adjust the provided annotation in response to modifications to the user-selected design element and to a physical version of the user-selected design element.

33. The apparatus of claim 21, wherein the AI-powered collaborative environment supports real-time collaborative annotations and modifications by multiple users.

34. The apparatus of claim 21, wherein the AI engine is further configured to compare the annotation or design elements against an integrated database of safety codes or standards to identify a potential non-compliance issue.

35. The apparatus of claim 34, further comprising an alert module configured to automatically alert users when the AI engine identifies any non-compliance issue, and to provide suggestions for compliance adjustments.

36. The apparatus of claim 21, further comprising an integration module configured to integrate at least one third-party platform for integrating code compliance services.

37. The apparatus of claim 21, wherein the AI engine is further configured to analyze the raster image to ascertain features included in the design plan, and to determine that a feature is located within a particular set of boundaries or external to the particular set of boundaries.

38. The apparatus of claim 21, wherein the AI engine is further configured to generate a value for element lengths, which values may also be calculated based on the design plan.

39. The apparatus of claim 21, wherein the AI engine is further configured to generate a user interface that includes dynamic components, wherein the dynamic components are further definable via user and/or machine manipulation.

40. The apparatus of claim 21, wherein the AI engine is further configured to analyze pixel patterns and enhanced vector diagrams and/or polygon-based diagrams to perform functions traditionally performed by a skilled labor force.
